(19) United States
(12) Patent Application Publication
(10) Pub. No.: US 2025/0132150 A1
(43) Pub. Date: Apr. 24, 2025

(54) CARRIER WAFER DEBONDING PROCESS AND METHOD

(71) Applicant: Taiwan Semiconductor manufacturing Co., Ltd., Hsinchu (TW)

(72) Inventors: Che Chi Shih, Taoyuan (TW); Chun-Yu Liu, New Taipei (TW); James June Fan Hsu, New Taipei (TW); Ku-Feng Yang, Baoshan Township (TW); Szuya Liao, Zhubei (TW)

(21) Appl. No.: 18/582,070

(22) Filed: Feb. 20, 2024

Related U.S. Application Data
(60) Provisional application No. 63/591,944, filed on Oct. 20, 2023.

(51) Int. Cl. H01L 21/02; H01L 21/324; H01L 29/66

(52) U.S. Cl. CPC H01L 21/02334; H01L 21/02293; H01L 21/02532; H01L 21/3245; H10D 30/024; H10D 64/017

(57) ABSTRACT

A method includes forming a first de-bond structure over a first substrate, where forming the first de-bond structure includes depositing a first de-bond layer over the first substrate, depositing a first silicon layer over the first de-bond layer, depositing a second de-bond layer over the first silicon layer, and depositing a second silicon layer over the second de-bond layer, epitaxially growing a first multi-layer stack over the first de-bond structure, bonding the first multi-layer stack to a second multi-layer stack, and performing a first laser annealing process to ablate the first silicon layer and portions of the first de-bond layer and the second de-bond layer in order to de-bond the first substrate from the first multi-layer stack.

### CROSS-REFERENCE TO RELATED APPLICATIONS

This application claims priority to U.S. Application No. 63/591,944, filed on Oct. 20, 2023, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2A through 11 illustrate varying views of intermediate stages in the manufacturing of CFETs, in accordance with some embodiments.

FIGS. 12 through 16 illustrate varying views of intermediate stages in the manufacturing of CFETs, in accordance with other embodiments.

FIGS. 17 through 20 are cross-sectional views of intermediate steps during a process for forming an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, stacking transistors, such as CFETs, are formed. A CFET includes an n-type nanostructure-FET and a p-type nanostructure-FET that are vertically stacked together. To form the CFET, a first superlattice (e.g., comprising NFET channel regions formed of first semiconductor layers) is epitaxially grown over a first substrate (e.g., a first carrier wafer), and a second superlattice (e.g., comprising PFET channel regions formed of second semiconductor layers) is epitaxially grown over a second substrate (e.g., a second carrier wafer). A de-bond structure may be formed between the first substrate and the first superlattice, or between the second substrate and the second superlattice. The first superlattice and the second superlattice are subsequently bonded together. The de-bond structure may comprise a multi-layer stack of alternating silicon layers and de-bond layers formed using chemical vapor deposition (CVD), atomic layer deposition (ALD), or the like. The multi-layer stack comprises between 2 to 5 silicon layers and between 2 to 5 de-bond layers. Each de-bond layer may comprise germanium (Ge), silicon germanium (SiGe), silicon carbide (SiC), or the like. A laser annealing process may performed to ablate a portion of the de-bond structure in order to de-bond the first substrate from the first superlattice, or to de-bond the second substrate from the second superlattice.

Advantageous features of one or more embodiments disclosed herein may allow for the formation of one or more resonant cavities in the de-bond structure that match the wavelength of the laser used during the laser annealing process. This allows an ablation threshold to be achieved within the de-bond structure, resulting in the ablation of a portion of the de-bond structure. The ablation of the portion of the de-bond structure allows for the de-bonding of the first substrate from the first superlattice, or the de-bonding of the second substrate from the second superlattice. This de-bonding of the first substrate from the first superlattice, or the de-bonding of the second substrate from the second superlattice is achieved with minimal damage to the first substrate or the second substrate. In this way, the first substrate or the second substrate are available for possible recycle and reuse in further semiconductor manufacturing operations (e.g., to form another CFET). As a result, manufacturing costs can be reduced. In addition, forming the de-bond structure using a multi-layer stack of alternating silicon layers and de-bond layers that are formed using CVD or ALD results in better film quality of the silicon layers and de-bond layers, as compared to if the silicon layers and de-bond layers were formed using other processes (e.g., plasma processes that result in plasma damage to the silicon layers and de-bond layers). As a result, the quality of the epitaxial layers of the first superlattice or the second superlattice that are formed over the de-bond structure is improved. Further, the de-bond structure comprises materials that are selected based on their lattice parameters to achieve improved lattice matching with the first superlattice or the second superlattice. In this way, strain and defects at the interfaces between the first superlattice and the de-bond structure, or between the second superlattice and the de-bond structure are reduced. This results in improved bonding between the first substrate and the first superlattice, or between the second substrate and the second superlattice.

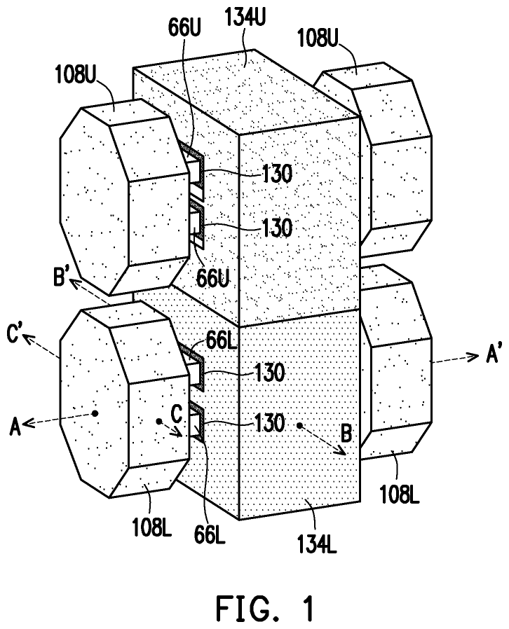

FIG. 1 illustrates an example of a CFET schematic, in accordance with some embodiments. FIG. 1 is a three-dimensional view, where some features of the CFETs are omitted for illustration clarity.

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. For simplicity, various embodiments may be described below in the context of manufacturing a CFET with a lower PMOS transistor and an upper NMOS transistor. However, it should be appreciated that various embodiments may also be applied to CFETs having a lower NMOS transistor and an upper PMOS transistor.

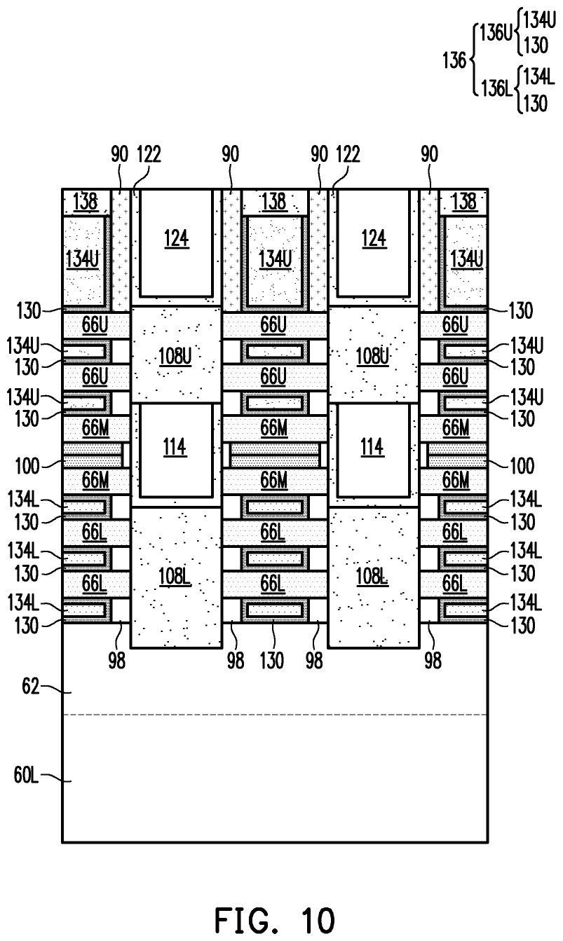

Each of the nanostructure-FETs include semiconductor nanostructures 66 (labeled lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIG. 10) may be used to separate and electrically isolate the upper semiconductor nanostructures 66U from the lower semiconductor nanostructures 66L.

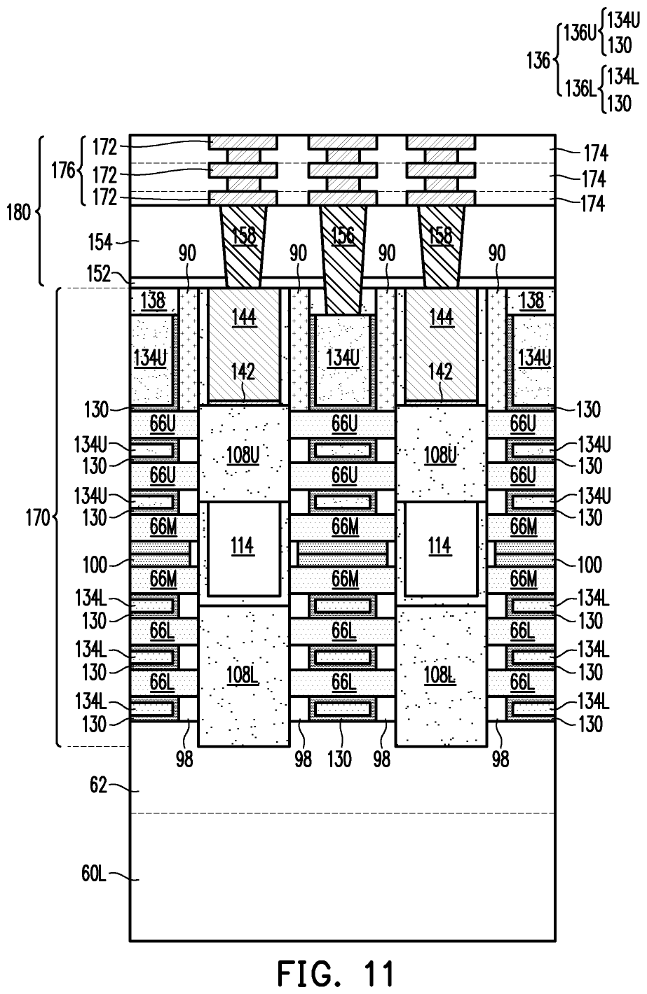

Gate dielectrics 130 are along top surfaces, sidewalls, and bottom surfaces of the semiconductor nanostructures 66. Gate electrodes 134 (including a lower gate electrode 134L and an upper gate electrode 134U) are over the gate dielectrics 130 and around the semiconductor nanostructures 66. Source/drain regions 108 (labeled lower epitaxial source/drain regions 108L and upper epitaxial source/drain regions 108U) are disposed at opposing sides of the gate dielectrics 130 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U. Alternatively, the lower gate electrode 134L may be coupled to the upper gate electrode 134U. Further, the upper epitaxial source/drain regions 108U may be separated from lower epitaxial source/drain regions 108L by one or more dielectric layers (not explicitly illustrated in FIG. 1, see FIG. 11). The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that may be used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures may refer to these reference cross-sections for clarity.

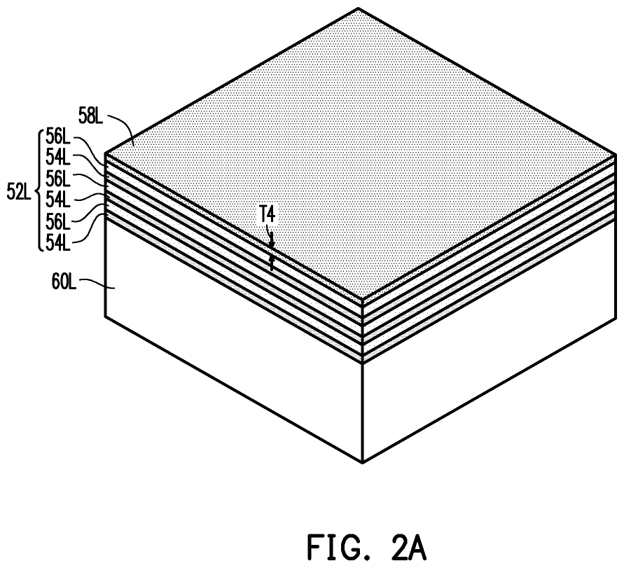

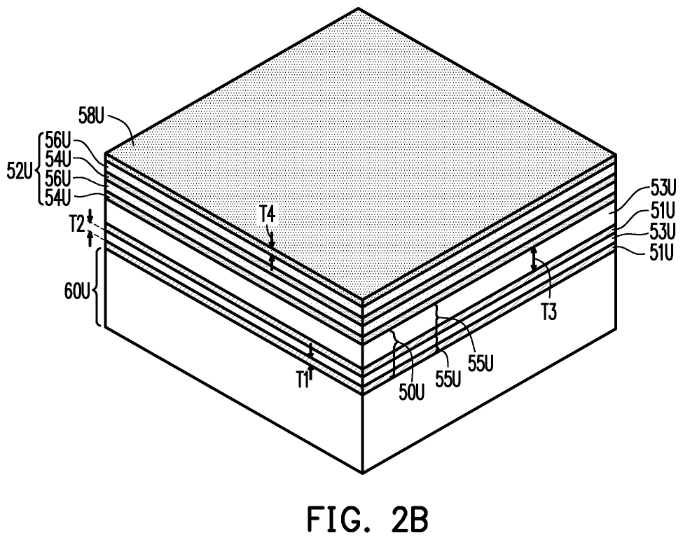

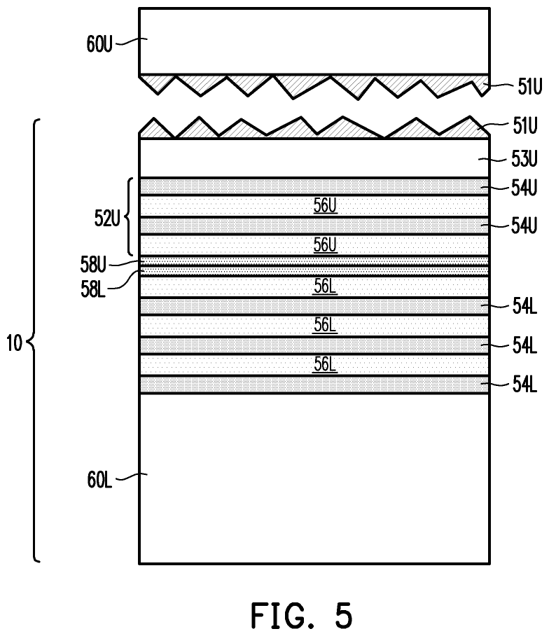

FIGS. 2A-11 are views of intermediate stages in the manufacturing of CFETs, in accordance with some embodiments. FIGS. 2A, 2B, 3, 4, and 7 are three-dimensional views showing a similar three-dimensional view as FIG. 1. FIGS. 5, 6, 8, 9, 10, and 11 illustrate cross-sectional views along a similar cross-section as reference cross-section A-A′ in FIG. 1.

In FIGS. 2A and 2B, two substrates 60L and 60U are separately provided.

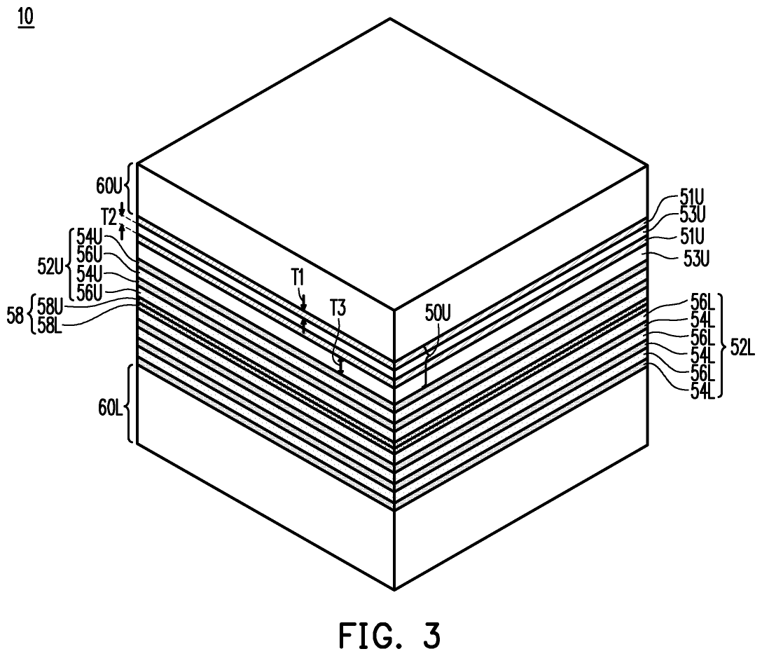

FIG. 2A illustrates a substrate 60L, and FIG. 2B illustrates a substrate 60U. In subsequently processes, the substrate 60U may be bonded over the substrate 60L (see FIG. 3). As such, the substrate 60L may be referred to as a lower substrate 60L, and the substrate 60U may also be referred to as an upper substrate 60U. Each of the substrates 60L and 60U may be a semiconductor substrate, such as a bulk semiconductor, a semiconductor-on-insulator (SOI) substrate, or the like, which may be doped (e.g., with a p-type or an n-type dopant) or undoped. The substrates 60L and 60U may each be a wafer, such as a silicon wafer. The substrates 60L and 60U may also be referred to subsequently as carrier wafers. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrates 60L and 60U may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Referring to FIG. 2B, a de-bond structure 50U is formed over the substrate 60U. The de-bond structure 50U may comprise a multi-layer stack of alternating de-bond layers 51U and silicon layers 53U that may be formed using physical vapor deposition (PVD), plasma-enhanced (ALD) PEALD, thermal ALD, microwave CVD (MWCVD), plasma-enhanced CVD (PECVD), hybrid-physical CVD (HPCVD), or the like. Each de-bond layer 51U may comprise germanium (Ge), silicon germanium (e.g., Si₁₋ₓGeₓ, where x is in a range from 0.7 to 1), silicon carbide (SiC), boron or phosphorus doped silicon, boron or phosphorus doped silicon germanium, yttrium oxide (Y₂O₃), cerium oxide (CeO₂), boron nitride (BN), gallium phosphide (GaP), titanium nitride (TiN), or the like. In an embodiment, a growth temperature during the formation of the de-bond layers 51U is in a range from 100° C. to 1400° C. In an embodiment, a growth temperature during the formation of the de-bond layers 51U is in a range from 400° C. to 800° C. In an embodiment, each de-bond layer 51U may comprise a material that has a crystal system that is cubic, hexagonal, tetragonal, orthorhombic, monoclinic, triclinic, or the like. In an embodiment, the de-bond layers 51U may comprise a material that has a single crystal structure, poly crystal structure, amorphous structure, or the like.

Forming the de-bond structure 50U may comprise forming a plurality of de-bond stacks 55U over the substrate 60U. Each de-bond stack 55U comprises a de-bond layer 51U and a corresponding silicon layer 53U over the de-bond layer 51U. The de-bond structure 50U may comprise 2 to 5 de-bond stacks 55U. For example, in FIG. 2B, the de-bond structure 50U is shown to comprise 2 de-bond stacks 55U. In other embodiments, the de-bond structure 50U may comprise up to 5 de-bond stacks 55U. In FIG. 2B, a first de-bond layer 51U (e.g. also referred to as a bottommost de-bond layer) may be formed over the substrate 60U. A corresponding first silicon layer 53U (also referred to as a bottommost silicon layer) is then formed over the first de-bond layer 51U to form a first de-bond stack 55U. More de-bond stacks 55U (comprising pairs of de-bond layers 51U and corresponding silicon layers 53U) are then formed over the first de-bond stack 55U to form the de-bond structure 50U. For example, in FIG. 2B, A second de-bond layer 51U (e.g. also referred to as a topmost de-bond layer) and a corresponding second silicon layer 53U (also referred to as a topmost silicon layer) are then formed sequentially over the first de-bond stack 55U to form a second de-bond stack 55U. In an embodiment, a thickness T1 of each de-bond layer 51U is in a range from 1 nm to 10 nm. In an embodiment, a thickness T2 of each silicon layer 53U may be in a range from 5 nm to 200 nm. In an embodiment, a thickness T3 of the topmost silicon layer (e.g., the second silicon layer 53U in FIG. 2B) is greater than 100 nm.

Referring back to FIGS. 2A and 2B, a multi-layer stack 52L (also referred to as a superlattice) and a multi-layer stack 52U (also referred to as a superlattice) are formed over the substrate 60L and the substrate 60U, respectively. Specifically, the multi-layer stack 52L is formed over and in contact with the substrate 60L, and the multi-layer stack 52U is formed over and in contact with the de-bond structure 50U. The multi-layer stack 52L includes alternating dummy semiconductor layers 54L and semiconductor layers 56L, and the multi-layer stack 52U includes alternating dummy semiconductor layers 54U and semiconductor layers 56U. The multi-layer stacks 52U and 52L will subsequently be bonded together, and the dummy semiconductor layers 54L and the semiconductor layers 56L will be disposed below the dummy semiconductor layers 54U and the semiconductor layers 56U (see FIG. 3). As such, the layers 54L and 56L may also be referred to as lower dummy semiconductor layers 54L and lower semiconductor layers 56L, respectively, and the layers 54U and 56U may be also be referred to as upper dummy semiconductor layers 54U and upper semiconductor layers 56U, respectively. As subsequently described in greater detail, the dummy semiconductor layers 54L and 54U will be removed and the semiconductor layers 56L and 56U will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stacks 52L and 52U are each illustrated as including a specific number of the dummy semiconductor layers 54L/54U and the semiconductor layers 56L/56U. It should be appreciated that the multi-layer stacks 52L and 52U may include any number of the dummy semiconductor layers 54L/54U and/or the semiconductor layers 56L/56U. Each layer of the multi-layer stacks 52L and 52U may be grown by a process such as vapor phase epitaxy (VPE) or molecular beam epitaxy (MBE), deposited by a process such as chemical vapor deposition (CVD) or atomic layer deposition (ALD), or the like.

The dummy semiconductor layers 54U and 54L are formed of a first semiconductor material selected from the candidate semiconductor materials of the substrates 60U and 60L. The semiconductor layers 56U and 56L are formed of one or more second semiconductor material(s). The second semiconductor material(s) may be selected from the candidate semiconductor materials of the substrates 60U and 60L. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon germanium, and the upper semiconductor layers 56U are formed of a semiconductor material suitable for n-type devices, such as silicon or carbon-doped silicon.

The semiconductor material(s) of the semiconductor layers 56U and 56L are different from and have a high etching selectivity to the semiconductor materials of the dummy semiconductor layers 54U and 54L. As such, the materials of the dummy semiconductor layers 54U and 54L may be removed at a faster rate than the material of the semiconductor layers 56U and 56L in subsequent processing. In some embodiments, the dummy semiconductor layers 54U and 54L are formed of silicon germanium, and the semiconductor layers 56U and 56L are formed of silicon. The silicon of the semiconductor layers 56U and 56L may be undoped or lightly doped at this step of processing.

Referring further to FIGS. 2A and 2B, insulating bonding layers 58L and 58U are deposited on the multi-layer stacks 52L and 52U, respectively. FIG. 2A illustrates a perspective view of the substrate 60L, the multi-layer stack 52L (including the dummy semiconductor layers 54L and the semiconductor layers 56L), and the bonding layer 58L; and FIG. 2B illustrates a perspective view of the substrate 60U, the de-bond structure 50U, the multi-layer stack 52U (including the dummy semiconductor layers 54U and the semiconductor layers 56U), and the bonding layer 58U. The bonding layers 58L and 58U may be deposited by any suitable process, such as physical vapor deposition (PVD), CVD, ALD, or the like. The bonding layers 58L and 58U may facilitate the bonding of the lower substrate 60L to the upper substrate 60U in subsequent processes (see FIG. 3). The bonding layers 58L and 58U may each comprise an insulating material that is suitable for a subsequent dielectric-to-dielectric bonding process. Example materials for the bonding layers 58L and 58U include silicon oxide (e.g., SiO₂), silicon nitride, silicon oxynitride, silicon carbonitride, silicon oxycarbonitride, silicon carbide, aluminum oxide, aluminum nitride, hafnium oxide, boron nitride, boron carbon nitride, yttrium oxide, or the like. A material composition of the bonding layer 58L may be the same or different than a material composition of the bonding layer 58U. In an embodiment, each of the bonding layers 58L and 58U may have a thickness T4 that is in a range from 0.5 nm to 50 nm.

In FIG. 3, the upper substrate 60U, having the multi-layer stack 52U disposed thereon, is placed over and bonded to the lower substrate 60L, having the multi-layer stack 52L disposed thereon, in order to form a bonded structure 10. As illustrated by FIG. 3, the bonded structure 10 includes the lower substrate 60L; the lower multi-layer stack 52L over the lower substrate 60L; the bonding layers 58L and 58U over the lower multi-layer stack 52L; the upper multi-layer stack 52U over the bonding layers 58L and 58U; the de-bond structure 50U over the multi-layer stack 52U, and the upper substrate 60U over the de-bond structure 50U. The upper substrate 60U may be bonded to the lower substrate 60L by the bonding layers 58L and 58U.

Specifically, the bonding layers 58L and 58U may be bonded together using a suitable technique, such as dielectric-to-dielectric bonding, or the like. The dielectric-to-dielectric bonding process may include performing a surface treatment to one or more bonding surfaces of the bonding layers 58L or 58U. The surface treatment may include a plasma treatment. After the surface treatment, the bonding layer 58U may be placed over and aligned to the bonding layer 58L. The two bonding layers 58L and 58U are then pressed against each other to initiate a pre-bonding of the upper substrate 60U to the lower substrate 60L. The pre-bonding be performed at room temperature (e.g., in a range of 25° C. to 26° C.). After the pre-bonding, an annealing process may be applied by, for example, heating the substrates 60L and 60U to an elevated temperature. After bonding, the lower bonding layer 58L and the upper bonding layer 58U may be collectively referred to as a bonded layer 58. The bonded layer 58 may or may not have an interface disposed therein where the bonding layer 58L meets the bonding layer 58U.

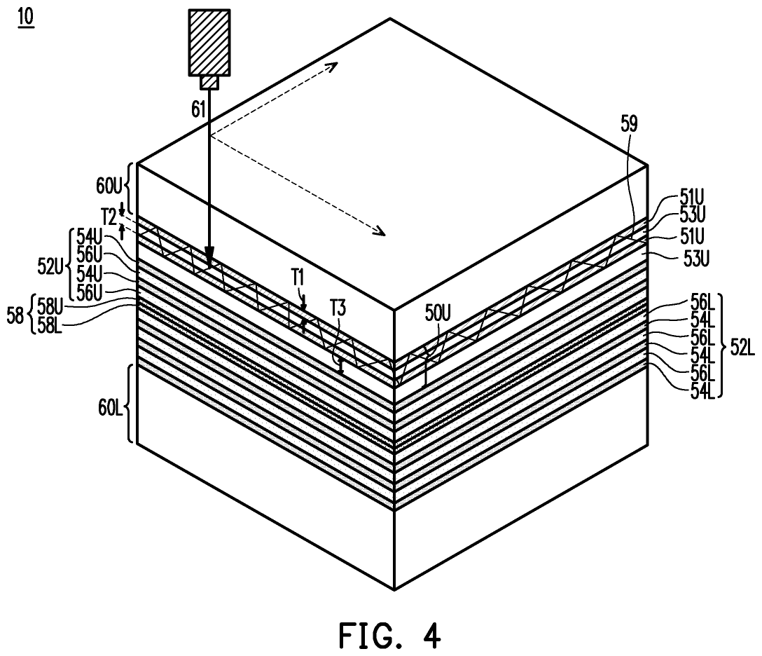

In FIG. 4, a laser annealing process 61 is performed using a laser to de-bond the upper substrate 60U from the topmost silicon layer (e.g., the second silicon layer 53U), the multi-layer stack 52U and the rest of the bonded structure 10. The laser annealing process 61 comprises systematically moving (e.g., scanning) a laser beam that is emitted from the laser over a top surface (e.g., a top surface of the upper substrate 60U) of the bonded structure 10 shown in FIG. 3. In an embodiment, the laser may operate in the infrared region with a wavelength that is in a range from 500 to 2500 nm. In an embodiment, the laser beam may have a power output that is in a range from 500 mW to 5000 mW. In an embodiment, the laser may emits pulses of laser light with durations on the order of picoseconds (1×10⁻¹² s). The laser beam may be able to penetrate through the upper substrate 60U to reach the de-bond structure 50U.

The de-bond structure 50U comprises one or more resonant cavities 59. A resonant cavity 59 may be formed in each combination of a silicon layer 53U and the de-bond layers 51U that are adjacent (that are disposed both above and below) to the silicon layer 53U. For example, in FIG. 4, a resonant cavity 59 is formed in the first silicon layer 53U, the first de-bond layer 51U, and the second de-bond layer 51U. In this way, a number of resonant cavities 59 that are formed in the de-bond structure 50U is equal to the number of silicon layers 53U that have corresponding adjacent de-bond layers 51U disposed both above and below each of the silicon layers 53U.

During the laser annealing process 61, the laser interacts with each resonant cavity 59 in a silicon layer 53U and its corresponding adjacent de-bond layers 51U. The wavelength of the laser beam emitted by the laser may match the resonant frequency of the resonant cavity 59, and the resonant cavity 59 may trap the electromagnetic waves produced by the laser, allowing them to resonate back and forth within the resonant cavity 59. This resonance increases the energy density of the laser within the resonance cavity 59, which can result in more efficient heating during the laser annealing process 61. As a result, an ablation threshold can be achieved within the de-bond structure 50U that allows for more effective material removal (e.g., through ablation) of the silicon layer 53U and its corresponding adjacent de-bond layers 51U. In this way, the upper substrate 60U is de-bonded from the topmost silicon layer (e.g., the second silicon layer 53U), the multi-layer stack 52U and the rest of the bonded structure 10 (shown subsequently in FIG. 5). It should be noted that no resonant cavity is formed in the topmost silicon layer (e.g., the second silicon layer 53U) of the de-bond structure 50U as it only has one de-bond layer 51U adjacent to it. After the laser annealing process 61, the topmost silicon layer (e.g., the second silicon layer 53U) remains on the multi-layer stack 52U. In an embodiment, the topmost silicon layer (e.g., the second silicon layer 53U) having the thickness T3 that is greater than 100 nm may help to prevent disruption or damage to the multi-layer stack 52U (also referred to as a superlattice) and the multi-layer stack 52L (also referred to as a superlattice) during the laser annealing process 61.

Further referring to FIG. 4, using the laser that operates in the infrared region to perform the laser annealing process 61 results in the creation of voids at interfaces between each silicon layer 53U and adjacent de-bond layers 51U that are disposed above and/or below the silicon layer 53U. As a result, the bonding forces between the silicon layer 53U and the adjacent de-bond layers 51U are weakened without causing significant thermal effects or damage to the upper substrate 60U or the multi-layer stack 52U. The created voids act as stress concentrators, and help to facilitate the de-bonding of the upper substrate 60U from the topmost silicon layer (e.g., the second silicon layer 53U) and the multi-layer stack 52U during the laser annealing process 61.

FIG. 5 illustrates the upper substrate 60U and the bonded structure 10 after the laser annealing process 61 is performed to de-bond the upper substrate 60U from the topmost silicon layer (e.g., the second silicon layer 53U), the multi-layer stack 52U, and the rest of the bonded structure 10. As a result of the laser annealing process 61, the first silicon layer 53U, and portions of the de-bond layers 51U (e.g., the first de-bond layer 51U and the second de-bond layer 51U) are ablated, which facilitates the de-bonding of the upper substrate 60U from the topmost silicon layer (e.g., the second silicon layer 53U), the multi-layer stack 52U, and the rest of the bonded structure 10.

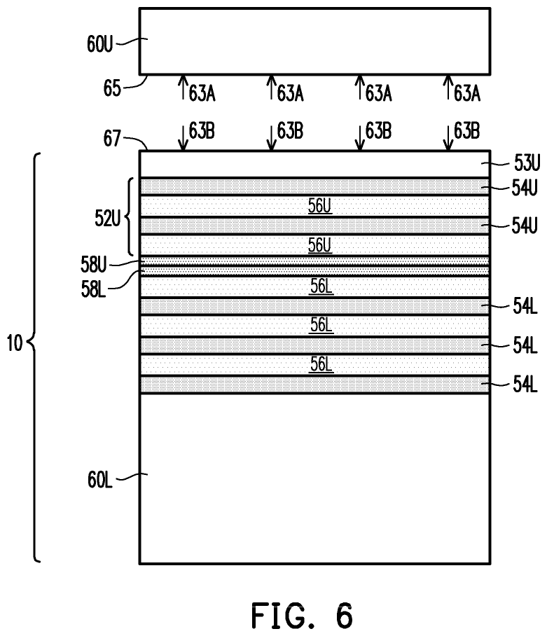

In FIG. 6, a wet etch process 63A is performed to remove remaining portions of the de-bond layer 51U (e.g., the first de-bond layer 51U) on a first surface 65 of the upper substrate 60U. In addition, a wet etch process 63B is performed to remove remaining portions of the de-bond layer 51U (e.g., the second de-bond layer 51U) on a first surface 67 of the topmost silicon layer (e.g., the second silicon layer 53U). The wet etch processes 63A and 63B may comprise using hydrogen peroxide (H₂O₂), de-ionized water, or hydrofluoric acid (HF) as etchants to remove the remaining portions of the first de-bond layer 51U on the first surface 65 of the upper substrate 60U, and the second de-bond layer 51U on the first surface 67 of the second silicon layer 53U. After the wet etch process 63A and the wet etch process 63B are performed, a surface clean process may be performed on surfaces of each of the upper substrate 60U and the bonded structure 10. The surface clean process may comprise exposing surfaces of each of the upper substrate 60U and the bonded structure 10 to a solution that comprises de-ionized water, ammonium hydroxide (NH₄OH), and hydrogen peroxide (H₂O₂). In an embodiment, a temperature of the solution during the surface clean process is in a range from 40° C. to 80° C.

Referring further to FIG. 6, after the wet etch process 63A, the wet etch process 63B, and the surface clean process have been performed, a planarization process may be performed on each of the first surface 65 of the upper substrate 60U, and the first surface 67 of the topmost silicon layer (e.g., the second silicon layer 53U). The planarization process may comprise a grinding process, a chemical mechanical polish (CMP), a combination thereof, or the like. The planarization process may also be used to reduce a thickness of the topmost silicon layer (e.g., the second silicon layer 53U) to match a thickness of each of the semiconductor layers 56U and/or 56L.

Advantages can be achieved by forming the de-bond structure 50U over the substrate 60U, the de-bond structure 50U comprising a plurality of de-bond stacks 55U. Each de-bond stack 55U comprises a de-bond layer 51U and a corresponding silicon layer 53U over the de-bond layer 51U, wherein the de-bond structure 50U comprises 2 to 5 de-bond stacks 55U. For example, the de-bond structure 50U may comprise the first de-bond layer 51U over the substrate 60U, the first silicon layer 53U over the first de-bond layer 51U, the second de-bond layer 51U over the first silicon layer 53U, and the second silicon layer 53U over the second de-bond layer 51U. Each de-bond layer 51U may comprise germanium (Ge), silicon germanium (e.g., Si₁₋ₓGeₓ, where x is in a range from 0.7 to 1), silicon carbide (SiC), boron or phosphorus doped silicon, boron or phosphorus doped silicon germanium, yttrium oxide (Y₂O₃), cerium oxide (CeO₂), boron nitride (BN), gallium phosphide (GaP), or titanium nitride (TiN). Each de-bond layer 51U has the thickness T1 that is in a range from 1 nm to 10 nm, and each silicon layer 53U has a thickness T2 that is in a range from 5 nm to 200 nm. The multi-layer stack 52U is formed over and in contact with the de-bond structure 50U, and after forming the multi-layer stack 52U, the multi-layer stack 52U is bonded to the multi-layer stack 52L. The laser annealing process 61 is then performed using a laser that operates in the infrared region with a wavelength that is in a range from 500 to 2500 nm, and which emits a laser beam that has a power output that is in a range from 500 mW to 5000 mW. The laser annealing process 61 results in the ablation of the first silicon layer 53U and portions of the first and second de-bond layers 51U, and further results in the de-bonding of the substrate 60U from the multi-layer stack 52U.

These advantages include each de-bond layer 51U having the thickness T1 that is in the range from 1 nm to 10 nm, and each silicon layer 53U having the thickness T2 that is in the range from 5 nm to 200 nm allowing for the formation of one or more resonant cavities 59 in the de-bond structure 50U that match the wavelength of the infrared laser used during the laser annealing process 61. This allows for more efficient heating of the de-bond structure 50U during the laser annealing process 61, which allows an ablation threshold to be achieved within the de-bond structure 50U, and results in more effective material removal (e.g., through ablation) of the first silicon layer 53U, and portions of the first and second de-bond layers 51U. This further results in the de-bonding of the substrate 60U from the multi-layer stack 52U. This de-bonding of the substrate 60U from the multi-layer stack 52U is achieved with minimal damage to the substrate 60U since the need to perform a trimming or thinning process on the substrate 60U to remove it from the multi-layer stack 52U is eliminated. In this way, the substrate 60U is available for possible recycle and reuse in further semiconductor manufacturing operations (e.g., to form another CFET). As a result, manufacturing costs can be reduced. In addition, forming the de-bond structure 50U using the plurality of de-bond stacks 55U comprising alternating silicon layers 53U and de-bond layers 51U that are formed using CVD or ALD results in better film quality of the silicon layers 53U and the de-bond layers 51U, as compared to if the silicon layers 53U and the de-bond layers 51U were formed using other processes (e.g., plasma processes that result in plasma damage to the silicon layers 53U and the de-bond layers 51U). As a result, the quality of the epitaxial layers of the multi-layer stack 52U that are formed over the de-bond structure 50U are improved. Further, the plurality of de-bond stacks 55U comprises materials that are selected based on their lattice parameters to achieve improved lattice matching with the multi-layer stack 52U. In this way, strain and defects at the interfaces between the multi-layer stack 52U and the de-bond structure 50U are reduced. This results in improved bonding between the substrate 60U and the multi-layer stack 52U when the multi-layer stack 52U is formed.

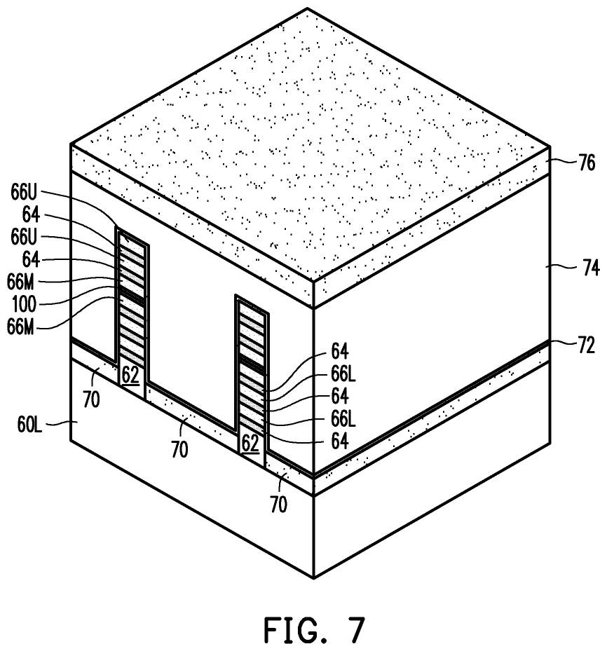

In FIG. 7, semiconductor fins 62 are formed in the lower substrate 60L. Further, nanostructures 64, 66 (including dummy nanostructures 64, lower semiconductor nanostructures 66L, middle semiconductor nanostructures 66M, and upper semiconductor nanostructures 66U) are formed in the topmost silicon layer (e.g., the second silicon layer 53U) and the multi-layer stacks 52L and 52U, and an isolation material 100 is formed from the bonded layer 58. In some embodiments, the nanostructures 64, 66, the isolation material 100, and the semiconductor fins 62 are formed by etching trenches in the topmost silicon layer (e.g., the second silicon layer 53U), the upper multi-layer stack 52U, the bonded layer 58, the lower multi-layer stack 52L, and the lower substrate 60L. The etching may be any acceptable etch process, such as a reactive ion etch (RIE), neutral beam etch (NBE), the like, or a combination thereof. The etching may be anisotropic. Forming the nanostructures 64, 66 may define the dummy nanostructure 64 from the lower dummy semiconductor layers 54L and the upper dummy semiconductor layers 54U, the lower semiconductor nanostructures 66L from some of the lower semiconductor layers 56L, the upper semiconductor nanostructures 66U from the topmost silicon layer (e.g., the second silicon layer 53U) and some of the upper semiconductor layers 56U, and the middle semiconductor nanostructures 66M from some of the lower semiconductor layers 56L and some of the upper semiconductor layers 56U. The lower semiconductor nanostructures 66L and the upper semiconductor nanostructures 66U may further be collectively referred to as the semiconductor nanostructures 66.

The lower semiconductor nanostructures 66L will act as channel regions for lower nanostructure-FETs of the CFETs. The upper semiconductor nanostructures 66U will act as channel regions for upper nanostructure-FETs of the CFETs. The middle semiconductor nanostructures 66M are the semiconductor nanostructures 66 that are directly above/below (e.g., in contact with) the isolation material 100. Depending on the heights of subsequently formed source/drain regions, the middle semiconductor nanostructures 66M may or may not adjoin any source/drain regions and may or may not act as functional channel regions for the CFETs. The isolation structures and the middle semiconductor nanostructures 66M may define boundaries of the lower nanostructure-FETs and the upper nanostructure-FETs.

The semiconductor fins 62, the nanostructures 64, 66, and the isolation material 100 may be patterned by any suitable method. For example, the semiconductor fins 62, the nanostructures 64, 66, and the isolation material 100 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62, the nanostructures 64, 66, and the isolation material 100. In some embodiments, a mask (or other layer) may remain on the nanostructures 64, 66.

Although each of the semiconductor fins 62, the nanostructures 64, 66, and the isolation material 100 are illustrated as having a constant width throughout, in other embodiments, the semiconductor fins 62, the nanostructures 64, 66, and/or the isolation material 100 may have tapered sidewalls such that a width of each of the semiconductor fins 62, the nanostructures 64, 66, and/or the isolation material 100 continuously increases in a direction towards the substrate 60L. In such embodiments, each of the nanostructures 64, 66 and the isolation material 100 may have a different width and be trapezoidal in shape.

Referring further to FIG. 7, after forming the semiconductor fins 62, the nanostructures 64, 66 (including dummy nanostructures 64, lower semiconductor nanostructures 66L, middle semiconductor nanostructures 66M, and upper semiconductor nanostructures 66U), and the isolation material 100, isolation regions 70 are formed over the lower substrate 60L and between adjacent semiconductor fins 62. The isolation regions 70 (also referred to as shallow trench isolation (STI) regions subsequently) may include a dielectric liner and a dielectric material over the dielectric liner. Each of the dielectric liner and the dielectric material may include an oxide such as silicon oxide, a nitride, such as silicon nitride, the like, or a combination thereof. The formation of the isolation regions 70 may include depositing the dielectric layer(s), and performing a planarization process such as a Chemical Mechanical Polish (CMP) process, a mechanical polishing process, or the like to remove excess portions of the dielectric materials, such as portions over the nanostructures 64, 66. The deposition processes may include ALD, High-Density Plasma CVD (HDP-CVD), Flowable CVD (FCVD), the like, or a combination thereof. In some embodiments, the isolation regions 70 include silicon oxide formed by an FCVD process, followed by an anneal process. Then, the dielectric layers(s) are recessed to define the isolation regions 70. The dielectric layer(s) may be recessed such that upper portions of semiconductor fins 62, the nanostructures 64, 66, and the isolation material 100 extend higher than the remaining isolation regions 70.

After the formation of the isolation regions 70, a dummy dielectric layer 72 is formed on the semiconductor fins 62, the nanostructures 64, 66, and/or the isolation material 100. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be made of other materials that have a high etching selectivity from the etching of isolation regions. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the semiconductor fins 62, the nanostructures 64, 66, and/or the isolation material 100.

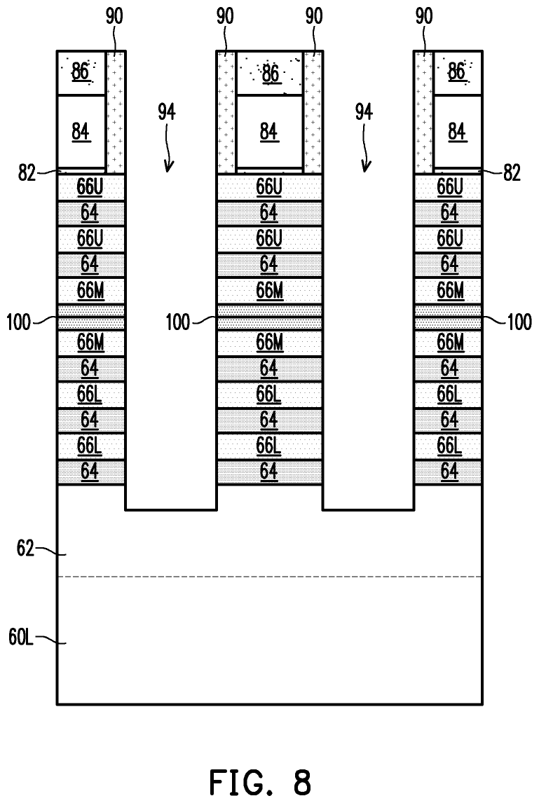

In FIG. 8, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective semiconductor fins 62. The masks 86 can optionally be removed after patterning, such as by any acceptable etching technique.

After the formation of the dummy gates 84 and the dummy dielectrics 82, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the semiconductor fins 62 and/or the nanostructures 64, 66.

Still referring to FIG. 8, after the formation of the gate spacers 90, source/drain recesses 94 are formed in the semiconductor fins 62, the nanostructures 64, 66, the isolation material 100, and the substrate 60L. Epitaxial source/drain regions will be subsequently formed in the source/drain recesses 94. The source/drain recesses 94 may extend through the nanostructures 64, 66, through the isolation material 100, and into the substrate 60L. The semiconductor fins 62 may be etched such that bottom surfaces of the source/drain recesses 94 are disposed above, below, or level with the top surfaces of the isolation regions 70. The source/drain recesses 94 may be formed by etching the semiconductor fins 62, the nanostructures 64, 66, the isolation material 100, and the substrate 60L using anisotropic etching processes, such as RIE, NBE, or the like. The gate spacers 90 and the dummy gates 84 mask portions of the semiconductor fins 62, the nanostructures 64, 66, the isolation material 100, and the substrate 60L during the etching processes used to form the source/drain recesses 94. A single etch process or multiple etch processes may be used to etch each layer of the nanostructures 64, 66, the isolation material 100, and/or the semiconductor fins 62. Timed etch processes may be used to stop the etching of the source/drain recesses 94 after the source/drain recesses 94 reach a desired depth.

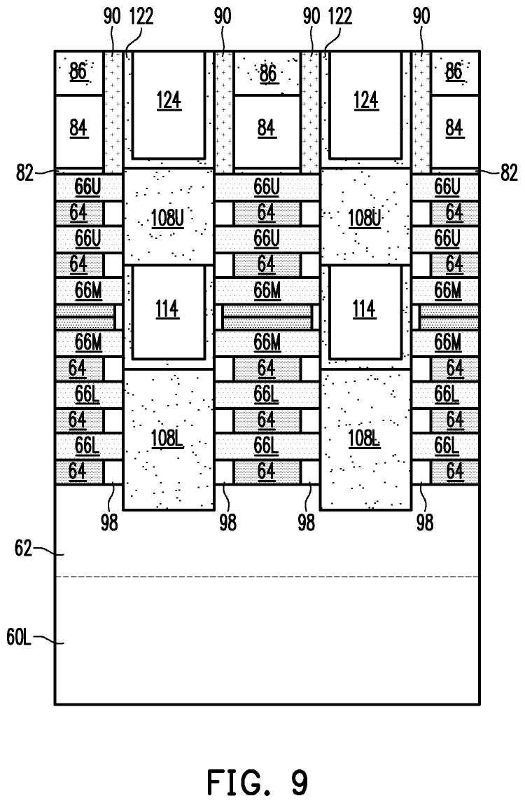

In FIG. 9, inner spacers 98 are formed on sidewalls of the dummy nanostructures 64 and the isolation material 100. To form the inner spacers 98, portions of the sidewalls of the dummy nanostructures 64 and the sidewalls of the isolation material 100 exposed by the source/drain recesses 94 are recessed to form sidewall recesses. The sidewall recesses may be formed by recessing the sidewalls of the dummy nanostructures 64 and isolation material 100 with any acceptable etch process. The etching is selective to the material of the dummy nanostructures 64 (e.g., selectively etches the material of the dummy nanostructures 64 at a faster rate than the material of the semiconductor nanostructures 66). The etching may further be selective to the material of the isolation material 100 (e.g., selectively etches the material of the isolation material 100 at a faster rate than the material of the semiconductor nanostructures 66). The etching may be isotropic. Although sidewalls of the dummy nanostructures 64 and the isolation material 100 are illustrated as being straight after the etching, the sidewalls may be concave or convex.

In some embodiments, the same etching process is used to recess the sidewalls of the dummy nanostructures 64 and the isolation material 100. Specifically, the etching process may selectively etch the material of the dummy nanostructures 64 at a faster rate (e.g., as illustrated in FIG. 9), a same rate, or a slower rate than the isolation material 100. The etching rate results in different relative sizes on sidewalls of the dummy nanostructures 64 compared to the isolation material 100. The relative etching rates of the dummy nanostructures 64 and the isolation material 100 may be achieved, for example, by tuning etching parameters of the etching process.

Inner spacers 98 are then formed in the sidewall recesses of the dummy nanostructures 64 and the isolation material 100. As subsequently described in greater detail, source/drain regions will be subsequently formed in the source/drain recesses 94, and the dummy nanostructures 64 will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures.

The inner spacers 98 may be formed by conformally forming an insulating material in the source/drain recesses 94, and then subsequently etching the insulating material. The insulating material may be a hard dielectric material, such as a carbon-containing dielectric material, such as silicon oxycarbonitride, silicon oxycarbide, silicon oxynitride, or the like. In an embodiment, the insulating material may comprise silicon oxycarbonitride having a carbon atomic percent of less than 6%. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses of the dummy nanostructures 64 and the isolation material 100 (thus forming the inner spacers 98).

Although outer sidewalls of the inner spacers 98 are illustrated as being flush with sidewalls of the semiconductor nanostructures 66, the outer sidewalls of the inner spacers 98 may extend beyond or be recessed from sidewalls of the semiconductor nanostructures 66. In other words, the inner spacers 98 may partially fill, completely fill, or overfill the sidewall recesses of the dummy nanostructures 64 and the isolation material 100. Moreover, although the sidewalls of the inner spacers 98 are illustrated as being straight, those sidewalls may be concave or convex.

Due to differences in size between the sidewall recesses of the dummy nanostructures 64 and the isolation material 100, inner spacers 98 on the isolation material 100 may also have a different size (e.g., width) than the inner spacers 98 on the dummy nanostructures 64. For example, in the illustrated embodiment, the inner spacers 98 on the isolation material 100 are less wide than the inner spacers 98 on the dummy nanostructures 64. In other embodiments, the inner spacers 98 on the isolation material 100 may be wider or have a same width as the inner spacers 98 on the dummy nanostructures 64.

Referring further to FIG. 9, after the formation of the inner spacers 98, lower and upper epitaxial source/drain regions 108L and 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the semiconductor fins 62. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first ILD 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed.

Upper epitaxial source/drain regions 108U are then formed in the upper portions of the source/drain recesses 94. The upper epitaxial source/drain regions 108U may be epitaxially grown from exposed surfaces of the upper semiconductor nanostructures 66U. The materials of upper epitaxial source/drain regions 108U may be selected from the same candidate group of materials for forming lower epitaxial source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. In an embodiment, the upper epitaxial source/drain regions 108U includes silicon which is doped with phosphorous, or the like, wherein a doping concentration of the upper epitaxial source/drain regions 108U is greater than 1×10²¹ cm⁻³. Adjacent upper epitaxial source/drain regions 108U may remain separated after the epitaxy process or may be merged.

After the upper epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the gate spacers 90, and the dummy gate stacks 82/84 are coplanar (within process variations). The planarization process may remove masks 86, or leave masks 86 unremoved.

FIG. 10 illustrates a replacement gate process to replace the dummy gate stacks 82/84 and the dummy nanostructures 64 with gate stacks 136. The replacement gate process includes first removing the dummy gate stacks 82/84 and the remaining portions of the dummy nanostructures 64. The masks 86 (if present) may also be removed. The dummy gate stacks 82/84 are removed in one or more etching processes, so that recesses are defined between the gate spacers 90 and the semiconductor nanostructures 66/dummy nanostructures 64 are exposed. The remaining portions of the dummy nanostructures 64 are then removed through etching, so that the recesses extend between the semiconductor nanostructures 66. In the etching process, the dummy nanostructures 64 is etched at a faster rate than the semiconductor nanostructures 66, the isolation material 100, and the inner spacers 98. The etching may be isotropic. For example, when the dummy nanostructures 64 are formed of silicon-germanium, and the semiconductor nanostructures 66 are formed of silicon, the etch process may include a wet etch process using tetramethylammonium hydroxide (TMAH), ammonium hydroxide (NH₄OH), or the like.

Then, gate dielectrics 130 are deposited in the recesses between the gate spacers 90 and on the exposed semiconductor nanostructures 66. The gate dielectrics 130 are conformally formed on the exposed surfaces of the recesses (the removed gate stacks 82/84 and the dummy nanostructures 64) including the semiconductor nanostructures 66, the isolation material 100, and the gate spacers 90. In some embodiments, the gate dielectrics 130 wrap around all (e.g., four) sides of the semiconductor nanostructures 66 and the isolation material 100. Specifically, the gate dielectrics 130 may be formed on the top surfaces of the semiconductor fins 62; on the top surfaces, the sidewalls, and the bottom surfaces of the semiconductor nanostructures 66U, 66L; on the exposed lateral surfaces and the sidewalls of the semiconductor nanostructures 66M, on the sidewalls of the isolation material 100; and on the sidewalls of the gate spacers 90. The gate dielectrics 130 may include an oxide such as silicon oxide or a metal oxide, a silicate such as a metal silicate, combinations thereof, multi-layers thereof, or the like. The gate dielectrics 130 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 130 may include molecular-beam deposition (MBD), ALD, PECVD, and the like. Although single-layered gate dielectrics 130 are illustrated, the gate dielectrics 130 may include multiple layers, such as an interfacial layer and an overlying high-k dielectric layer.

Lower gate electrodes 134L are formed on the gate dielectrics 130 around the lower semiconductor nanostructures 66L. For example, the lower gate electrodes 134L wrap around the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of material(s) that are suitable for the device type of the lower nanostructure-FETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, molybdenum, zirconium, erbium, magnesium, strontium, and combinations thereof.

The lower gate electrodes 134L may be formed by conformally depositing one or more gate electrode layer(s), and then recessing the gate electrode layer(s). Any acceptable etch process, such as a dry etch, a wet etch, the like, or a combination thereof, may be performed to recess the gate electrode layer(s) 134L to a desired level (e.g., at or below a level of the isolation material 100). The etching may be isotropic. Etching the lower gate electrodes 134L may expose the upper semiconductor nanostructures 66U.

In some embodiments, isolation layers (not explicitly illustrated) may be optionally formed on the lower gate electrodes 134L. The isolation layers act as isolation features between the lower gate electrodes 134L and subsequently formed upper gate electrodes 134U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 66U.

Then, upper gate electrodes 134U are formed on the isolation layers described above (if present) or the lower gate electrodes 134L. The upper gate electrodes 134U are disposed between the upper semiconductor nanostructures 66U. In some embodiments, the upper gate electrodes 134U wrap around the upper semiconductor nanostructures 66U. The upper gate electrodes 134U may be formed of the same candidate materials and candidate processes for forming the lower gate electrodes 134L. The upper gate electrodes 134U are formed of material(s) that are suitable for the device type of the upper nanostructure-FETs. For example, the upper gate electrodes 134U may include one or more work function tuning layer(s) formed of material(s) that are suitable for the device type of the upper nanostructure-FETs. Although single-layered gate electrodes 134U are illustrated, the upper gate electrodes 134U may include any number of work function tuning layers, any number of barrier layers, any number of glue layers, and a fill material.

Additionally, one or more removal processes are performed to level top surfaces of the upper gate electrodes 134U and the gate dielectrics 130 with the second ILD 124. The removal process for forming the gate dielectrics 130 may be the same removal process as the removal process for forming the upper gate electrodes 134U. In some embodiments, a planarization process such as a chemical mechanical polish (CMP), an etch-back process, combinations thereof, or the like may be utilized. After the planarization process, the top surfaces of the upper gate electrodes 134U, the gate dielectrics 130, the second ILD 124, and the gate spacers 90 are substantially coplanar (within process variations). Each respective pair of a gate dielectric 130 and a gate electrode 134 (including an upper gate electrode 134U and/or a lower gate electrode 134L) may be collectively referred to as a “gate stack” 136 (including upper gate stacks 136U and lower gate stacks 136L). Each gate stack 136 extends along three sides (e.g., a top surface, a sidewall, and a bottom surface) of a channel region of a semiconductor nanostructure 66 (see FIG. 1). The lower gate stacks 136L may also extend along sidewalls and/or a top surface of a semiconductor fin 62.

As also shown in FIGS. 10, gate masks 138 are formed over the gate stacks 136. The formation process may include recessing gate stacks 136, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 124.

In FIG. 11, silicide regions 142 and source/drain contacts 144 are formed through the second ILD 124 to electrically couple to the upper epitaxial source/drain regions 108U and/or the lower epitaxial source/drain regions 108L. As an example to form the source/drain contacts 144, openings are formed through the second ILD 124 and the second CESL 122 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90 and the second ILD 124. The remaining liner and conductive material form the source/drain contacts 144 in the openings. In some embodiments, a planarization process such as a CMP, an etch-back process, combinations thereof, or the like is utilized. After the planarization process, the top surfaces of the gate spacers 90, the second ILD 124, and the source/drain contacts 144 are substantially coplanar (within process variations).

Optionally, metal-semiconductor alloy regions 142 are formed at the interfaces between the source/drain regions 108 and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142. The active devices as illustrated are collectively referred to as a device layer 170.

Further referring to FIG. 11, an etch stop layer (ESL) 152 and a third ILD 154 are then formed. In some embodiments, The ESL 152 may include a dielectric material having a high etching selectivity from the etching of the third ILD 154, such as, aluminum oxide, aluminum nitride, silicon oxycarbide, or the like. The third ILD 154 may be formed using flowable CVD, ALD, or the like, and the material may include PSG, BSG, BPSG, USG, or the like, which may be deposited by any suitable method, such as CVD, PECVD, or the like.

Subsequently, gate contacts 156 and source/drain vias 158 are formed to contact the upper gate stacks 136U and the source/drain contacts 144, respectively. As an example to form the gate contacts 156 and the source/drain vias 158, openings for the gate contacts 156 and the source/drain vias 158 are formed through the third ILD 154, the ESL 152, and the gate masks 138. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the gate contacts 156 and the source/drain vias 158 in the openings. The gate contacts 156 and the source/drain vias 158 may be formed in distinct processes, or may be formed in the same process. Although shown as being formed in the same cross-section, it should be appreciated that each of the gate contacts 156 and the source/drain vias 158 may be formed in different cross-sections, which may avoid shorting of the contacts. In some embodiments, contacts to the lower gate stacks 136L and the lower epitaxial source/drain regions 108L may be made through a backside of the device layer 170 (e.g., a side opposite to source/drain contacts 144).

A front-side interconnect structure 176 is then formed on the device layer 170, the gate contacts 156, the source/drain vias 158 and the third ILD 154. The front-side interconnect structure 176 includes dielectric layers 174 and layers of conductive features 172 in the dielectric layers 174. The dielectric layers 174 may include low-k dielectric layers formed of low-k dielectric materials. The dielectric layers 174 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 174 may also include polymer layers.

The conductive features 172 may include conductive lines and vias, which may be formed using damascene processes. The conductive features 172 may include metal lines and metal vias, which includes diffusion barriers and a copper containing material over the diffusion barriers. There may also be aluminum pads over and electrically connected to the metal lines and vias. The conductive features 172 may be electrically connected to the gate contacts 156 and the source/drain vias 158. The front-side interconnect structure 176, the gate contacts 156, the source/drain vias 158 and the third ILD 154 may be collectively referred to as a structure 180.

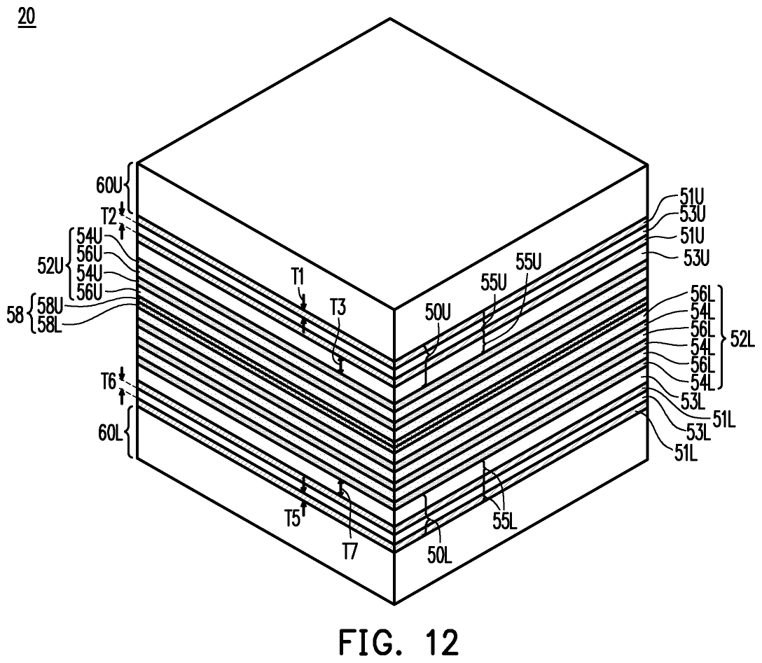

FIGS. 12 through 16 illustrate an alternative embodiment. Unless specified otherwise, like reference numerals in this embodiment (and subsequently discussed embodiments) represent like components in the embodiment shown in FIGS. 1 through 11 formed by like processes. Accordingly, the process steps and applicable materials may not be repeated herein. FIG. 12 illustrates a bonded structure 20 which may be similar to the bonded structure 10 of FIG. 3, unless specified otherwise. The difference between the bonded structure 20 of FIG. 12 and the bonded structure 10 of FIG. 3 is that the bonded structure 20 may also comprise a de-bond structure 50L that is disposed between the substrate 60L and the multi-layer stack 52L. The de-bond structure 50L may be formed using similar materials and similar processes as those that were described previously for the formation of the de-bond structure 50U in FIG. 2B.

Forming the de-bond structure 50L may comprise forming a plurality of de-bond stacks 55L over the substrate 60L. Each de-bond stack 55L comprises a de-bond layer 51L and a corresponding silicon layer 53L over the de-bond layer 51L. The de-bond structure 50L may comprise 2 to 5 de-bond stacks 55L. For example, in FIG. 12, the de-bond structure 50L is shown to comprise 2 de-bond stacks 55L. In other embodiments, the de-bond structure 50L may comprise up to 5 de-bond stacks 55L. In FIG. 12, a first de-bond layer 51L (e.g. also referred to as a bottommost de-bond layer) may be formed over the substrate 60L. A corresponding first silicon layer 53L (also referred to as a bottommost silicon layer) is then formed over the first de-bond layer 51L to form a first de-bond stack 55L. More de-bond stacks 55L (comprising pairs of de-bond layers 51L and corresponding silicon layers 53L) are then formed over the first de-bond stack 55L to form the de-bond structure 50L. For example, in FIG. 12, A second de-bond layer 51L (e.g. also referred to as a topmost de-bond layer) and a corresponding second silicon layer 53L (also referred to as a topmost silicon layer) are then formed sequentially over the first de-bond stack 55L to form a second de-bond stack 55L. In an embodiment, a thickness T5 of each de-bond layer 51L is in a range form 1 nm to 10 nm. In an embodiment, a thickness T6 of each silicon layer 53L may be in a range from 5 nm to 200 nm. In an embodiment, a thickness Ty of the topmost silicon layer (e.g., the second silicon layer 53L in FIG. 12) is greater than 100 nm. The de-bond layers 51L and the silicon layers 53L may be formed using similar processes and materials as the de-bond layers 51U and the silicon layers 53U, respectively, which were described previously in FIG. 2B. After the formation of the de-bond structure 50L, the multi-layer stack 52L is formed over and in contact with the de-bond structure 50L, in a similar manner as was described previously in FIG. 2B for the formation of the multi-layer stack 52U over and in contact with the de-bond structure 50U.

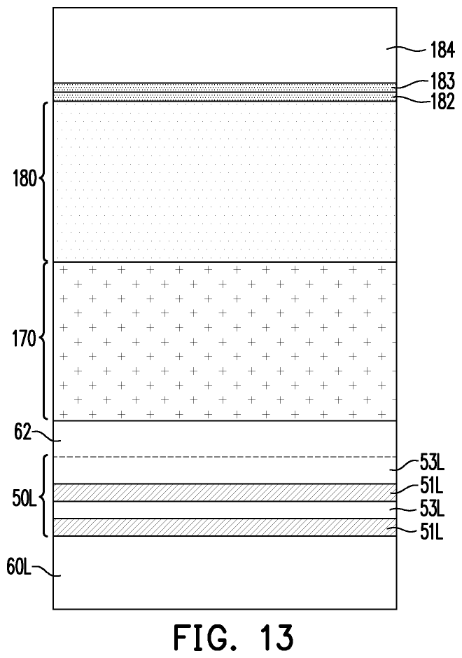

In FIG. 13, the same steps shown in FIGS. 4 through 11 are performed to form the device layer 170 (shown previously in FIG. 11) and the structure 180 (shown previously in FIG. 11) sequentially over the lower substrate 60L and the de-bond structure 50L.

After the formation of the device layer 170 and the structure 180, a substrate 184 (e.g., a silicon substrate, a silicon wafer, or the like) is bonded to a top surface of the structure 180 using a suitable technique such as fusion bonding, or the like. For example, in various embodiments, the substrate 184 may be bonded to the structure 180 using bonding layers 182/183 on the surfaces of the structure 180 and the substrate 184, respectively. In some embodiments, the bonding layers 182/183 may each comprise silicon oxide formed on the surfaces of the structure 180 and the substrate 184, respectively, by a deposition process, such as chemical vapor deposition (CVD), physical vapor deposition (PVD), or the like. In other embodiments, the bonding layer 183 may be formed by the thermal oxidation of silicon surfaces on the substrate 184.

Prior to bonding, at least one of the bonding layers 182/183 may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to one or both bonding layers 182/183. The substrate 184 is then aligned with the structure 180 and the two are pressed against each other to bond them together at room temperature (between about 21 degrees and about 25 degrees). The bonding process may be strengthened by a subsequent annealing step. For example, this may be done by heating the substrate 184 and the structure 180 to a temperature in a range from 140° C. to 500° C.

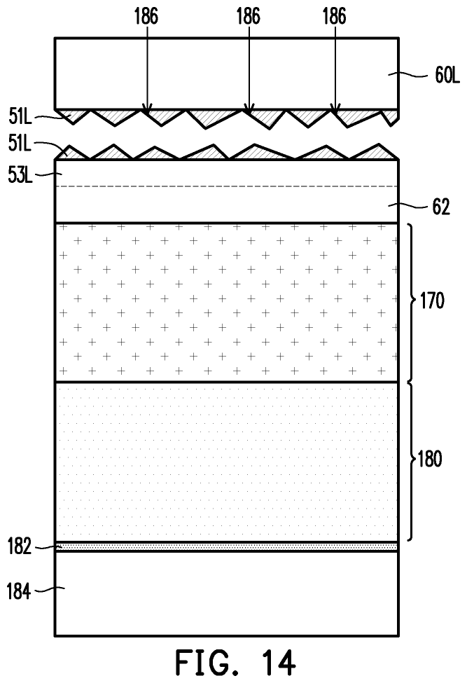

In FIG. 14, the structure shown previously in FIG. 13 may be flipped over such that the lower substrate 60L is disposed over the substrate 184. A laser annealing process 186 is then performed using a laser to de-bond the lower substrate 60L from the topmost silicon layer (e.g., the second silicon layer 53L), the device layer 170 and the structure 180. The laser annealing process 186 may be similar to the laser annealing process 61 that was described previously in FIG. 4. The laser annealing process 186 may comprise systematically moving (e.g., scanning) a laser beam that is emitted from the laser over a top surface of the lower substrate 60L that is shown in FIG. 14. As a result of the laser annealing process 186, an ablation threshold can be achieved within the de-bond structure 50L that allows for effective material removal (e.g., through ablation) of the first silicon layer 53L (also referred to as a bottommost silicon layer), and portions of the first de-bond layer 51L and the second de-bond layer 51L. In this way, the lower substrate 60L is de-bonded from the topmost silicon layer (e.g., the second silicon layer 53L), the device layer 170, and the structure 180.

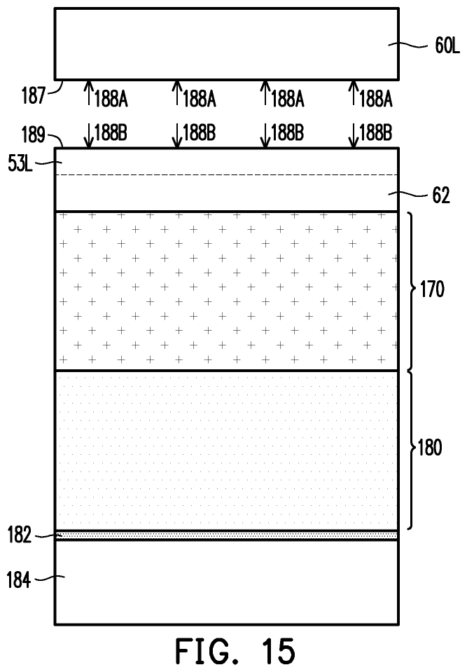

In FIG. 15, a wet etch process 188A is performed to remove remaining portions of the de-bond layer 51L (e.g., the first de-bond layer 51L) on a first surface 187 of the lower substrate 60L. In addition, a wet etch process 188B is performed to remove remaining portions of the de-bond layer 51L (e.g., the second de-bond layer 51L) on a first surface 189 of the topmost silicon layer (e.g., the second silicon layer 53L). The wet etch processes 188A and 188B may comprise using hydrogen peroxide (H₂O₂), de-ionized water, or hydrofluoric acid (HF) as etchants to remove the remaining portions of the de-bond layer 51L (e.g., the first de-bond layer 51L) on the first surface 187 of the lower substrate 60L, and the de-bond layer 51L (e.g., the second de-bond layer 51L) on the first surface 189 of the topmost silicon layer (e.g., the second silicon layer 53L). After the wet etch process 188A and the wet etch process 188B are performed, a surface clean process may be performed on surfaces of each of the lower substrate 60L and the topmost silicon layer (e.g., the second silicon layer 53L). The surface clean process may comprise exposing surfaces of each of the upper substrate 60U and the topmost silicon layer (e.g., the second silicon layer 53L) to a solution that comprises de-ionized water, ammonium hydroxide (NH₄OH), and hydrogen peroxide (H₂O₂). In an embodiment, a temperature of the solution during the surface clean process is in a range from 40° C. to 80° C.

Referring further to FIG. 15, after the wet etch process 188A, the wet etch process 188B, and the surface clean process have been performed, a planarization process may be performed on each of the first surface 187 of the lower substrate 60L, and the first surface 189 of the topmost silicon layer (e.g., the second silicon layer 53L). The planarization process may comprise a grinding process, a chemical mechanical polish (CMP), a combination thereof, or the like.

Advantages can be achieved by forming the de-bond structure 50L over the substrate 60L, the de-bond structure 50L comprising a plurality of de-bond stacks 55L. Each de-bond stack 55L comprises a de-bond layer 51L and a corresponding silicon layer 53L over the de-bond layer 51L, wherein the de-bond structure 50L comprises 2 to 5 de-bond stacks 55L. For example, the de-bond structure 50L may comprise the first de-bond layer 51L over the substrate 60L, the first silicon layer 53L over the first de-bond layer 51L, the second de-bond layer 51L over the first silicon layer 53L, and the second silicon layer 53L over the second de-bond layer 51L. Each de-bond layer 51L may comprise germanium (Ge), silicon germanium (e.g., Si₁₋ₓGeₓ, where x is in a range from 0.7 to 1), silicon carbide (SiC), boron or phosphorus doped silicon, boron or phosphorus doped silicon germanium, yttrium oxide (Y₂O₃), cerium oxide (CeO₂), boron nitride (BN), gallium phosphide (GaP), or titanium nitride (TiN). Each de-bond layer 51L has the thickness T5 that is in a range from 1 nm to 10 nm, and each silicon layer 53L has a thickness T6 that is in a range from 5 nm to 200 nm. The multi-layer stack 52L is formed over and in contact with the de-bond structure 50L, and after forming the multi-layer stack 52L, the multi-layer stack 52L is bonded to the multi-layer stack 52U. The laser annealing process 186 is then performed using a laser that operates in the infrared region with a wavelength that is in a range from 500 to 2500 nm, and which emits a laser beam that has a power output that is in a range from 500 mW to 5000 mW. The laser annealing process 186 results in the ablation of the first silicon layer 53L and portions of the first and second de-bond layers 51L, and further results in the de-bonding of the substrate 60L from the multi-layer stack 52L.

These advantages include each de-bond layer 51L having the thickness T5 that is in the range from 1 nm to 10 nm, and each silicon layer 53L having the thickness T6 that is in the range from 5 nm to 200 nm allowing for the formation of one or more resonant cavities (e.g., similar to resonant cavity 59 described previously in FIG. 4) in the de-bond structure 50L (e.g., in the first silicon layer 53L, the first de-bond layer 51L, and the second de-bond layer 51L) that match the wavelength of the infrared laser used during the laser annealing process 186. This allows for more efficient heating of the de-bond structure 50L during the laser annealing process 186, which allows an ablation threshold to be achieved within the de-bond structure 50L, and results in more effective material removal (e.g., through ablation) of the first silicon layer 53L, and portions of the first and second de-bond layers 51L. This further results in the de-bonding of the substrate 60L from the multi-layer stack 52L. This de-bonding of the substrate 60L from the multi-layer stack 52L is achieved with minimal damage to the substrate 60L since the need to perform a trimming or thinning process on the substrate 60L to remove it from the multi-layer stack 52L is eliminated. In this way, the substrate 60L is available for possible recycle and reuse in further semiconductor manufacturing operations (e.g., to form another CFET). As a result, manufacturing costs can be reduced. In addition, forming the de-bond structure 50L using the plurality of de-bond stacks 55L comprising alternating silicon layers 53L and de-bond layers 51L that are formed using CVD or ALD results in better film quality of the silicon layers 53L and the de-bond layers 51L, as compared to if the silicon layers 53L and the de-bond layers 51L were formed using other processes (e.g., plasma processes that result in plasma damage to the silicon layers 53L and the de-bond layers 51L). As a result, the quality of the epitaxial layers of the multi-layer stack 52L that are formed over the de-bond structure 50L are improved. Further, the plurality of de-bond stacks 55L comprises materials that are selected based on their lattice parameters to achieve improved lattice matching with the multi-layer stack 52L. In this way, strain and defects at the interfaces between the multi-layer stack 52L and the de-bond structure 50L are reduced. This results in improved bonding between the substrate 60L and the multi-layer stack 52L when the multi-layer stack 52L is formed.

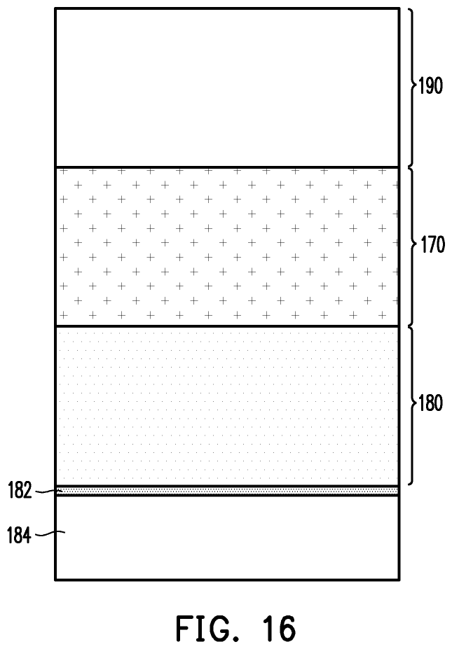

In FIG. 16, a further thinning process is applied to the planarized first surface 189 (shown previously in FIG. 15) to remove the topmost silicon layer (e.g., the second silicon layer 53L) and the semiconductor fins 62. The thinning process may include a grinding process, a chemical mechanical polish (CMP), an etch back process, combination thereof, or the like. After the thinning process, lower epitaxial source/drain regions 108L (e.g., shown previously in FIG. 11) of the device layer 170 may be exposed.

After the thinning process to remove the topmost silicon layer (e.g., the second silicon layer 53L) and the semiconductor fins 62 is performed, a structure 190 is formed over the device layer 170. The structure 190 may comprise a fourth ILD disposed over the device layer, and gate contact plugs and source/drain vias extending through the fourth ILD to contact the lower gate stacks 136L (e.g., shown previously in FIG. 11) and the lower epitaxial source/drain regions 108L (e.g., shown previously in FIG. 11), respectively. The structure 190 may also comprise a back-side interconnect structure that is disposed over the device layer 170, the gate contact plugs, the source/drain vias and the fourth ILD. The back-side interconnect structure includes dielectric layers and layers of conductive features in the dielectric layers. The conductive features may be electrically connected to the gate contact plugs and the source/drain vias. The structure 190 may be formed using similar processes and similar materials as were used for the formation of the structure 180 that was described previously in FIG. 11. For example, processes and materials used for the formation of the fourth ILD, the gate contact plugs, and the source/drain vias may be similar to those used for the formation of the third ILD 154, the gate contacts 156, and the source/drain vias 158, respectively, that were described previously in FIG. 11. Further, processes and materials used for the formation of the back-side interconnect structure may be similar to those used for the formation of the front-side interconnect structure 176 that was described previously in FIG. 11.

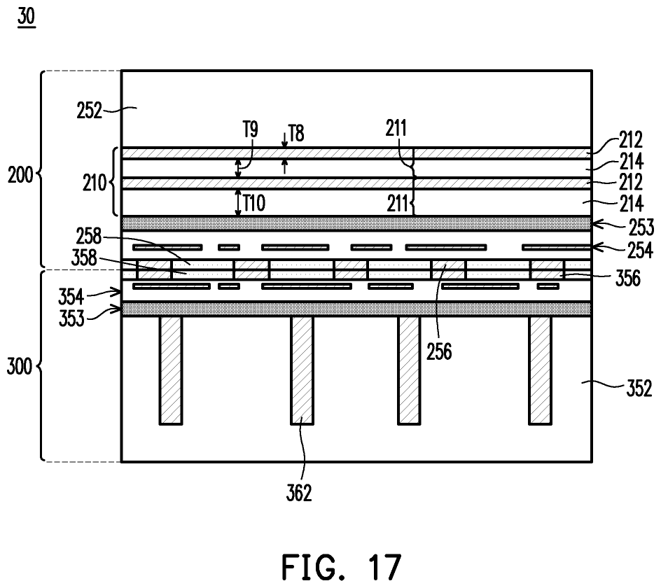

FIGS. 17 through 20 illustrate an alternative embodiment. Unless specified otherwise, like reference numerals in this embodiment (and subsequently discussed embodiments) represent like components in the embodiment shown in FIGS. 1 through 16 formed by like processes. Accordingly, the process steps and applicable materials may not be repeated herein. FIGS. 17 through 20 are cross-sectional views of intermediate steps during a process for forming an integrated circuit package 30 (e.g., a system-on-integrated-chip (SoIC) device, or the like), in accordance with some embodiments.

FIG. 17 illustrates the bonding of a wafer 200 (e.g. a top die, or the like) to a wafer 300 (e.g., a bottom die, or the like), in accordance with embodiments. Each of the wafer 200 or the wafer 300 may comprise a logic die (e.g., central processing unit (CPU), graphics processing unit (GPU), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof (e.g., a system-on-a-chip (SoC) die). Each of the wafer 200 and the wafer 300 may include different die regions that are singulated in subsequent steps to form a plurality of die regions.

Further referring to FIG. 17, the wafer 200 comprises a substrate 252, and a de-bond structure 210 formed over the substrate 252. The substrate 252 (which also may be referred to as a carrier substrate or a carrier wafer) may be a substrate of silicon, doped or undoped, or an active layer of a semiconductor-on-insulator (SOI) substrate. The substrate 252 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used.

The de-bond structure 210 of the wafer 200 is formed over the substrate 252. The de-bond structure 210 may be formed using similar materials and similar processes as those that were described previously for the formation of the de-bond structure 50U in FIG. 2B, and the de-bond structure 50L in FIG. 12. For example, forming the de-bond structure 210 may comprise forming a plurality of de-bond stacks 211 over the substrate 252. Each de-bond stack 211 comprises a de-bond layer 212 and a corresponding silicon layer 214 over the de-bond layer 212. The de-bond structure 210 may comprise 2 to 5 de-bond stacks 211. For example, in FIG. 17, the de-bond structure 210 is shown to comprise 2 de-bond stacks 211. In other embodiments, the de-bond structure 210 may comprise up to 5 de-bond stacks 211. In FIG. 17, a first de-bond layer 212 (e.g. also referred to as a bottommost de-bond layer) may be formed over the substrate 252. A corresponding first silicon layer 214 (also referred to as a bottommost silicon layer) is then formed over the first de-bond layer 212 to form a first de-bond stack 211. More de-bond stacks 211 (comprising pairs of de-bond layers 212 and corresponding silicon layers 214) are then formed over the first de-bond stack 211 to form the de-bond structure 210. For example, in FIG. 17, A second de-bond layer 212 (e.g. also referred to as a topmost de-bond layer) and a corresponding second silicon layer 214 (also referred to as a topmost silicon layer) are then formed sequentially over the first de-bond stack 211 to form a second de-bond stack 211. In an embodiment, a thickness T8 of each de-bond layer 212 is in a range from 1 nm to 10 nm. In an embodiment, a thickness T9 of each silicon layer 214 may be in a range from 5 nm to 200 nm. In an embodiment, a thickness T10 of the topmost silicon layer (e.g., the second silicon layer 214) is greater than 100 nm. The de-bond layers 212 and the silicon layers 214 may be formed using similar processes and materials as those used for the formation of the de-bond layers 51U and the silicon layers 53U, respectively, which were described previously in FIG. 2B.

After the formation of the de-bond structure 210, an active device layer 253 is formed in/or on the topmost silicon layer (e.g., the second silicon layer 214). The active device layer 253 may comprise active devices (e.g., transistors, diodes, etc.), capacitors, resistors, etc. The interconnect structure 254 of the wafer 200 is disposed over the active device layer 253, and is used to electrically connect the devices of the active device layer 253 to form an integrated circuit. The interconnect structure 254 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layer(s) may include conductive vias and/or conductive lines to interconnect the devices of the active device layer 253. The metallization layer(s) may be formed of a conductive material, such as a metal, such as copper, cobalt, aluminum, gold, combinations thereof, or the like. The interconnect structure 254 may be formed by a damascene process, such as a single damascene process, a dual damascene process, or the like.

Conductive connectors 256 are shown which may be in and/or on the interconnect structure 254 of the wafer 200. For example, the conductive connectors 256 may be part of an upper metallization layer of the interconnect structure 254. The conductive connectors 256 can be formed of a metal, such as copper, aluminum, or the like, and can be formed by, for example, plating, or the like. The conductive connectors 256 may be conductive pillars, pads, or the like, to which external connections are made.

A dielectric layer 258 is in and/or on the interconnect structure 254. For example, the dielectric layer 258 may be an upper dielectric layer of the interconnect structure 254. The dielectric layer 258 laterally encapsulates the conductive connectors 256. The dielectric layer 258 may be an oxide, a nitride, a carbide, a polymer, the like, or a combination thereof. The dielectric layer 258 may be formed, for example, by spin coating, lamination, chemical vapor deposition (CVD), or the like. Initially, the dielectric layer 258 may bury the conductive connectors 256, such that the top surface of the dielectric layer 258 is above the top surfaces of the conductive connectors 256. The conductive connectors 256 may be exposed through the dielectric layer 258 by a removal process that can be applied to the various layers to remove excess materials over the conductive connectors 256. The removal process may be a planarization process such as a chemical mechanical polish (CMP), an etch-back, combinations thereof, or the like.

The wafer 300 may have a structure similar to what is described for the wafer 200, and the details are not repeated herein. The materials of the features in the wafer 300 may be found by referring to the like features in the wafer 200, with the like features in the wafer 200 starting with number “2,” which features correspond to the features in the wafer 300 and having reference numerals starting with number “3.” Conductive vias 362 may be formed through the wafer 300 to allow external connections to be made to the subsequently formed integrated circuit package 30. The conductive vias 362 may be through-substrate vias (TSVs), such as through-silicon vias or the like. The conductive vias 362 extend through a substrate 352 of the wafer 300, to be physically and electrically connected to the metallization layer(s) of an interconnect structure 354 of the wafer 300. The interconnect structure 354 is disposed over the substrate 352 and an active device layer 353 that is formed in/or on the substrate 352.

Further referring to FIG. 17, the wafer 200 and the wafer 300 are bonded such that the active device layers 253/353 are facing each other (e.g., are “face-to-face” bonded). The dielectric layer 258 of the wafer 200 is bonded to a dielectric layer 358 of the wafer 300 through dielectric-to-dielectric bonding, without using any adhesive material (e.g., die attach film), and the conductive connectors 256 of the wafer 200 are bonded to conductive connectors 356 of the wafer 300 through metal-to-metal bonding, without using any eutectic material (e.g., solder). The bonding may include a pre-bonding and an annealing. During the pre-bonding, a small pressing force is applied to press the wafer 200 against the wafer 300. The pre-bonding is performed at a low temperature, such as room temperature, such as a temperature in the range of 15° C. to 30° C., and after the pre-bonding, the dielectric layer 258 and the dielectric layer 358 are bonded to each other. The bonding strength is then improved in a subsequent annealing step, in which the dielectric layer 258 and the dielectric layer 358 are annealed at a high temperature, such as a temperature in the range of 140° C. to 500° C. After the annealing, bonds, such as fusions bonds, are formed bonding the dielectric layer 258 and the dielectric layer 358. For example, the bonds can be covalent bonds between the material of the dielectric layer 258 and the material of the dielectric layer 358. The conductive connectors 256 and the conductive connectors 356 are connected to each other with a one-to-one correspondence. The conductive connectors 256 and the conductive connectors 356 may be in physical contact after the pre-bonding, or may expand to be brought into physical contact during the annealing. Further, during the annealing, the material of the conductive connectors 256 and the conductive connectors 356 (e.g., copper) intermingles, so that metal-to-metal bonds are also formed. Hence, the resulting bonds between the wafer 200 and the wafer 300 are hybrid bonds that include both dielectric-to-dielectric bonds and metal-to-metal bonds.

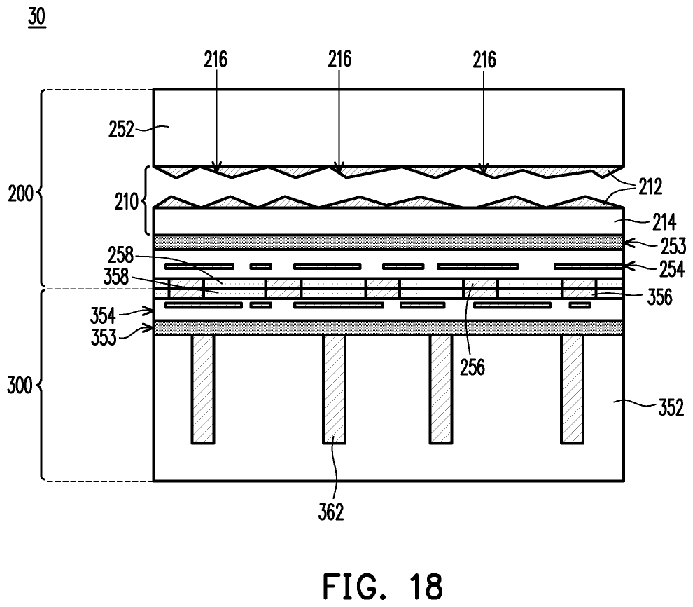

In FIG. 18, the structure shown previously in FIG. 17 may be positioned such that the wafer 200 is disposed over the wafer 300. A laser annealing process 216 is then performed using a laser to de-bond the substrate 252 from the topmost silicon layer (e.g., the second silicon layer 214), the interconnect structure 254, and the wafer 300. The laser annealing process 216 may be similar to the laser annealing process 61 that was described previously in FIG. 4, and the laser annealing process 186 that was described previously in FIG. 14. The laser annealing process 216 may comprise systematically moving (e.g., scanning) a laser beam that is emitted from the laser over a top surface of the substrate 252 that is shown in FIG. 18. As a result of the laser annealing process 216, an ablation threshold can be achieved within the de-bond structure 210 that allows for effective material removal (e.g., through ablation) of the first silicon layer 214 (also referred to as a bottommost silicon layer), and portions of the first de-bond layer 212 and the second de-bond layer 212. In this way, the substrate 252 is de-bonded from the topmost silicon layer (e.g., the second silicon layer 214), the interconnect structure 254, and the wafer 300.

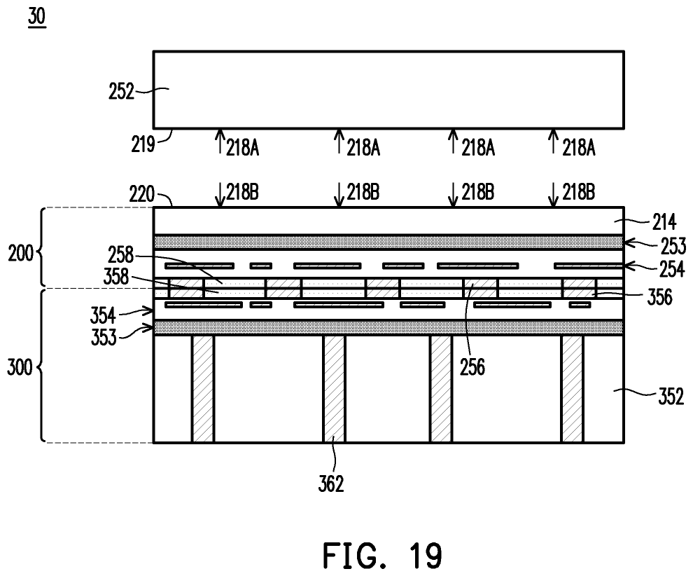

In FIG. 19, a wet etch process 218A is performed to remove remaining portions of the de-bond layer 212 (e.g., the first de-bond layer 212) on a first surface 219 of the substrate 252. In addition, a wet etch process 218B is performed to remove remaining portions of the de-bond layer 212 (e.g., the second de-bond layer 212) on a first surface 220 of the topmost silicon layer (e.g., the second silicon layer 214). The wet etch processes 218A and 218B may comprise using hydrogen peroxide (H₂O₂), de-ionized water, or hydrofluoric acid (HF) as etchants to remove the remaining portions of the de-bond layer 212 (e.g., the first de-bond layer 212) on the first surface 219 of the substrate 252, and the de-bond layer 212 (e.g., the second de-bond layer 212) on the first surface 220 of the topmost silicon layer (e.g., the second silicon layer 214). After the wet etch process 218A and the wet etch process 218B are performed, a surface clean process may be performed on surfaces of each of the substrate 252 and the topmost silicon layer (e.g., the second silicon layer 214). The surface clean process may comprise exposing surfaces of each of the substrate 252 and the topmost silicon layer (e.g., the second silicon layer 214) to a solution that comprises de-ionized water, ammonium hydroxide (NH₄OH), and hydrogen peroxide (H₂O₂). In an embodiment, a temperature of the solution during the surface clean process is in a range from 40° C. to 80° C.

Referring further to FIG. 19, after the wet etch process 218A, the wet etch process 218B, and the surface clean process have been performed, a first planarization process such as CMP, or the like, may then be performed on a bottom surface of the substrate 352 to expose the conductive vias 362 of the wafer 300. A second planarization process may be performed on each of the first surface 219 of the substrate 252, and the first surface 220 of the topmost silicon layer (e.g., the second silicon layer 214). The second planarization process may comprise a grinding process, a chemical mechanical polish (CMP), a combination thereof, or the like.

Advantages can be achieved by forming the de-bond structure 210 over the substrate 252 of the wafer 200, the de-bond structure 210 comprising a plurality of de-bond stacks 211. Each de-bond stack 211 comprises a de-bond layer 212 and a corresponding silicon layer 214 over the de-bond layer 212, wherein the de-bond structure 210 comprises 2 to 5 de-bond stacks 211. For example, the de-bond structure 210 may comprise the first de-bond layer 212 over the substrate 252, the first silicon layer 214 over the first de-bond layer 212, the second de-bond layer 212 over the first silicon layer 214, and the second silicon layer 214 over the second de-bond layer 212. Each de-bond layer 212 may comprise germanium (Ge), silicon germanium (e.g., Si₁₋ₓGeₓ, where x is in a range from 0.7 to 1), silicon carbide (SiC), boron or phosphorus doped silicon, boron or phosphorus doped silicon germanium, yttrium oxide (Y₂O₃), cerium oxide (CeO₂), boron nitride (BN), gallium phosphide (GaP), or titanium nitride (TiN). Each de-bond layer 212 has the thickness T8 that is in a range from 1 nm to 10 nm, and each silicon layer 214 has a thickness T9 that is in a range from 5 nm to 200 nm. After bonding the wafer 200 to the wafer 300, the laser annealing process 216 is then performed using a laser that operates in the infrared region with a wavelength that is in a range from 500 to 2500 nm, and which emits a laser beam that has a power output that is in a range from 500 mW to 5000 mW. The laser annealing process 216 results in the ablation of the first silicon layer 214 and portions of the first and second de-bond layers 212, and further results in the de-bonding of the substrate 252 from the topmost silicon layer (e.g., the second silicon layer 214), the interconnect structure 254 of the wafer 200, and the wafer 300.

These advantages include each de-bond layer 212 having the thickness T8 that is in a range from 1 nm to 10 nm, and each silicon layer 214 having the thickness T9 that is in a range from 5 nm to 200 nm allowing for the formation of one or more resonant cavities (e.g., similar to the resonant cavity 59 described previously in FIG. 4) in the de-bond structure 210 (e.g., in the first silicon layer 214, the first de-bond layer 212, and the second de-bond layer 212) that match the wavelength of the infrared laser used during the laser annealing process 216. This allows for more efficient heating of the de-bond structure 210 during the laser annealing process 216, which allows an ablation threshold to be achieved within the de-bond structure 210, and results in more effective material removal (e.g., through ablation) of the first silicon layer 214, and portions of the first and second de-bond layers 212. This further results in the de-bonding of the substrate 252 from the topmost silicon layer (e.g., the second silicon layer 214), the interconnect structure 254 of the wafer 200, and the wafer 300. This de-bonding of the substrate 252 from the topmost silicon layer (e.g., the second silicon layer 214), the interconnect structure 254 of the wafer 200, and the wafer 300 is achieved with minimal damage to the substrate 252 since the need to perform a trimming or thinning process on the substrate 252 to remove it from the wafer 200 and the wafer 300 is eliminated. In this way, the substrate 252 is available for possible recycle and reuse in further semiconductor manufacturing operations (e.g., to form another CFET). As a result, manufacturing costs can be reduced.

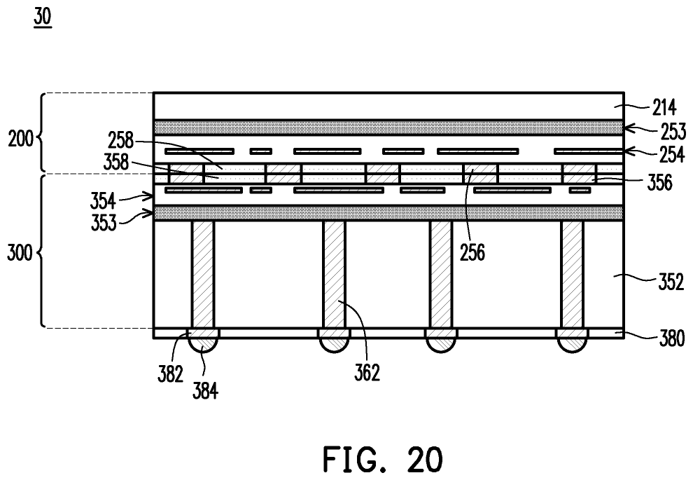

FIG. 20 illustrates the formation of contact pads 382 and a dielectric layer 380 on the planarized bottom surface of the substrate 352 and the exposed conductive vias 362 of the wafer 300. The dielectric layer 380 may be an oxide such as silicon oxide, PSG, BSG, BPSG, or the like; a nitride such as silicon nitride or the like; a polymer such as polybenzoxazole (PBO), polyimide, a benzocyclobutene (BCB) based polymer, or the like; or a combination thereof. The dielectric layer 380 may be formed, for example, by spin coating, lamination, chemical vapor deposition (CVD), or the like. The contact pads 382 may be used for connections to other devices. In some embodiments, the contact pads 382 are conductive bumps that are suitable for use with reflowable connectors, such as microbumps, extending through the dielectric layer 380. In the illustrated embodiment, the contact pads 382 are formed through the dielectric layer 380. As an example to form the contact pads 382, openings are formed in the dielectric layer 380, and a seed layer is formed over the dielectric layer 380 and in the openings. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the contact pads 382. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, such as copper, nickel, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the contact pads 382.

After the formation of the contact pads 382, conductive connectors 384 are formed on the contact pads 382. The conductive connectors 384 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 384 may include a conductive material such as solder, copper, aluminum, gold, nickel, silver, palladium, tin, the like, or a combination thereof. In some embodiments, the conductive connectors 384 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 384 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 384 are electrically connected to the interconnect structure 254 of the wafer 200 through the conductive vias 362 and the interconnect structure 354 of the wafer 300. The conductive connectors 384 may be used to electrically connect the integrated circuit package 30 to external devices, such as a package substrate, or the like.

The embodiments of the present disclosure have some advantageous features. The embodiments include forming a CFET, wherein to form the CFET, a first superlattice (e.g., comprising NFET channel regions formed of first semiconductor layers) is epitaxially grown over a first substrate (e.g., a first carrier wafer), and a second superlattice (e.g., comprising PFET channel regions formed of second semiconductor layers) is epitaxially grown over a second substrate (e.g., a second carrier wafer). A de-bond structure may be formed between the first substrate and the first superlattice, or between the second substrate and the second superlattice. The first superlattice and the second superlattice are subsequently bonded together. The de-bond structure may comprise a multi-layer stack of alternating silicon layers and de-bond layers formed using chemical vapor deposition (CVD), atomic layer deposition (ALD), or the like. The multi-layer stack comprises between 2 to 5 silicon layers and between 2 to 5 de-bond layers. Each de-bond layer may comprise germanium (Ge), silicon germanium (SiGe), silicon carbide (SiC), or the like. A laser annealing process may performed to ablate a portion of the de-bond structure in order to de-bond the first substrate from the first superlattice, or to de-bond the second substrate from the second superlattice.

One or more embodiments disclosed herein may allow for the formation of one or more resonant cavities in the de-bond structure that match the wavelength of the infrared laser used during the laser annealing process. This allows an ablation threshold to be achieved within the de-bond structure, resulting in the ablation of a portion of the de-bond structure. The ablation of the portion of the de-bond structure allows for the de-bonding of the first substrate from the first superlattice, or the de-bonding of the second substrate from the second superlattice. This de-bonding of the first substrate from the first superlattice, or the de-bonding of the second substrate from the second superlattice is achieved with minimal damage to the first substrate or the second substrate. In this way, the first substrate or the second substrate are available for possible recycle and reuse in further semiconductor manufacturing operations (e.g., to form another CFET). As a result, manufacturing costs can be reduced. In addition, forming the de-bond structure using a multi-layer stack of alternating silicon layers and de-bond layers that are formed using CVD or ALD results in better film quality of the silicon layers and de-bond layers, as compared to if the silicon layers and de-bond layers were formed using other processes (e.g., plasma processes that result in plasma damage to the silicon layers and de-bond layers). As a result, the quality of the epitaxial layers of the first superlattice or the second superlattice that are formed over the de-bond structure is improved. Further, the de-bond structure comprises materials that are selected based on their lattice parameters to achieve improved lattice matching with the first superlattice or the second superlattice. In this way, strain and defects at the interfaces between the first superlattice and the de-bond structure, or between the second superlattice and the de-bond structure are reduced. This results in improved bonding between the first substrate and the first superlattice, or between the second substrate and the second superlattice.

In accordance with an embodiment, a method includes forming a first de-bond structure over a first substrate, where forming the first de-bond structure includes depositing a first de-bond layer over the first substrate; depositing a first silicon layer over the first de-bond layer; depositing a second de-bond layer over the first silicon layer; and depositing a second silicon layer over the second de-bond layer; epitaxially growing a first multi-layer stack over the first de-bond structure; bonding the first multi-layer stack to a second multi-layer stack; and performing a first laser annealing process to ablate the first silicon layer and portions of the first de-bond layer and the second de-bond layer in order to de-bond the first substrate from the first multi-layer stack. In an embodiment, the method further includes patterning the second silicon layer, the first multi-layer stack, and the second multi-layer stack to form a fin, the fin including a plurality of lower nanostructures alternatingly stacked with first dummy nanostructures and a plurality of upper nanostructures over the plurality of lower nanostructures, the plurality of upper nanostructures being alternatingly stacked with second dummy nanostructures. In an embodiment, the method further includes replacing the first dummy nanostructures with a first gate stack, the first gate stack surrounding each of the plurality of lower nanostructures; and replacing the second dummy nanostructures with a second gate stack, the second gate stack surrounding each of the plurality of upper nanostructures. In an embodiment, performing the first laser annealing process includes scanning a laser beam that is emitted by a laser over a top surface of the first substrate, where the laser operates in an infrared region with a wavelength that is in a range from 500 to 2500 nm. In an embodiment, during performing the first laser annealing process, the laser beam has a power output that is in a range from 500 mW to 5000 mW. In an embodiment, a resonant cavity is formed in the combination of the first silicon layer, the first de-bond layer, and the second de-bond layer, and where during the performing of the first laser annealing process, the laser interacts with the resonant cavity. In an embodiment, a thickness of each of the first de-bond layer and the second de-bond layer is in a range from 1 nm to 10 nm. In an embodiment, a thickness of the first silicon layer is in a range from 5 nm to 200 nm. In an embodiment, each of the first de-bond layer and the second de-bond layer includes germanium, silicon germanium, silicon carbide, boron or phosphorus doped silicon, boron or phosphorus doped silicon germanium, yttrium oxide, cerium oxide, boron nitride, gallium phosphide, or titanium nitride.

In accordance with an embodiment, a method includes depositing a first de-bond layer over a first substrate; depositing a first silicon layer over the first de-bond layer; depositing a second de-bond layer over the first silicon layer; depositing a second silicon layer over the second de-bond layer; epitaxially growing a first semiconductor layer and a second semiconductor layer over the second silicon layer; epitaxially growing a third semiconductor layer and a fourth semiconductor layer over a second substrate; depositing a first bonding layer over the second semiconductor layer; depositing a second bonding layer over the fourth semiconductor layer; bonding the first bonding layer to the second bonding layer to form a bonded layer; and after bonding the first bonding layer to the second bonding layer, ablating the first de-bond layer, the first silicon layer, and the second de-bond layer using a laser anneal process to de-bond the first substrate from the second silicon layer, the first semiconductor layer, and the second semiconductor layer. In an embodiment, the method further includes patterning the third semiconductor layer, the fourth semiconductor layer, the bonded layer, the second semiconductor layer, and the first semiconductor layer to define a fin extending upwards from the first substrate. In an embodiment, the method further includes patterning source/drain recesses in the fin; forming first source/drains in the source/drain recesses; depositing a first isolation layer over the first source/drains; and forming second source/drains in the source/drain recesses over the first isolation layer. In an embodiment, a thickness of each of the first de-bond layer and the second de-bond layer is in a range from 1 nm to 10 nm. In an embodiment, the laser anneal process includes using a laser beam that is emitted from a laser to heat the first de-bond layer, the first silicon layer, and the second de-bond layer. In an embodiment, the laser operates in an infrared region with a wavelength that is in a range from 500 to 2500 nm.

In accordance with an embodiment, a method includes forming a first de-bond structure over a first substrate, where the first de-bond structure includes a resonant cavity, and where the first de-bond structure includes a first de-bond layer; a first semiconductor layer over the first de-bond layer; and a second de-bond layer over the first semiconductor layer; epitaxially growing a first multi-layer stack over the first de-bond structure; bonding the first multi-layer stack to a second multi-layer stack; and performing a first laser annealing process using a laser beam having a wavelength that matches a resonant frequency of the resonant cavity in order to ablate the first semiconductor layer and portions of the first de-bond layer and the second de-bond layer, and where performing the first laser annealing process results in a de-bonding of the first substrate from the first multi-layer stack. In an embodiment, the method further includes patterning the first multi-layer stack and the second multi-layer stack to form a fin, the fin including a plurality of lower nanostructures alternatingly stacked with first dummy nanostructures and a plurality of upper nanostructures over the plurality of lower nanostructures, the plurality of upper nanostructures being alternatingly stacked with second dummy nanostructures; replacing the first dummy nanostructures with a first gate stack, the first gate stack surrounding each of the plurality of lower nanostructures; and replacing the second dummy nanostructures with a second gate stack, the second gate stack surrounding each of the plurality of upper nanostructures. In an embodiment, the first semiconductor layer includes silicon, and where a thickness of the first semiconductor layer is in a range from 5 nm to 200 nm. In an embodiment, the first semiconductor layer includes silicon, and where a thickness of the first semiconductor layer is in a range from 5 nm to 200 nm. In an embodiment, a thickness of each of the first de-bond layer and the second de-bond layer is in a range from 1 nm to 10 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first de-bond structure over a first substrate, wherein forming the first de-bond structure comprises:
depositing a first de-bond layer over the first substrate;
depositing a first silicon layer over the first de-bond layer;
depositing a second de-bond layer over the first silicon layer; and
depositing a second silicon layer over the second de-bond layer;
epitaxially growing a first multi-layer stack over the first de-bond structure;
bonding the first multi-layer stack to a second multi-layer stack; and
performing a first laser annealing process to ablate the first silicon layer and portions of the first de-bond layer and the second de-bond layer in order to de-bond the first substrate from the first multi-layer stack.

2. The method of claim 1 further comprising:
patterning the second silicon layer, the first multi-layer stack, and the second multi-layer stack to form a fin, the fin comprising a plurality of lower nanostructures alternatingly stacked with first dummy nanostructures and a plurality of upper nanostructures over the plurality of lower nanostructures, the plurality of upper nanostructures being alternatingly stacked with second dummy nanostructures.

3. The method of claim 2 further comprising:
replacing the first dummy nanostructures with a first gate stack, the first gate stack surrounding each of the plurality of lower nanostructures; and
replacing the second dummy nanostructures with a second gate stack, the second gate stack surrounding each of the plurality of upper nanostructures.

4. The method of claim 1, wherein performing the first laser annealing process comprises scanning a laser beam that is emitted by a laser over a top surface of the first substrate, wherein the laser operates in an infrared region with a wavelength that is in a range from 500 to 2500 nm.

5. The method of claim 4, wherein during performing the first laser annealing process, the laser beam has a power output that is in a range from 500 mW to 5000 mW.

6. The method of claim 5, wherein a resonant cavity is formed in the combination of the first silicon layer, the first de-bond layer, and the second de-bond layer, and wherein during the performing of the first laser annealing process, the laser interacts with the resonant cavity.

7. The method of claim 1, wherein a thickness of each of the first de-bond layer and the second de-bond layer is in a range from 1 nm to 10 nm.

8. The method of claim 1, wherein a thickness of the first silicon layer is in a range from 5 nm to 200 nm.

9. The method of claim 1, wherein each of the first de-bond layer and the second de-bond layer comprises germanium, silicon germanium, silicon carbide, boron or phosphorus doped silicon, boron or phosphorus doped silicon germanium, yttrium oxide, cerium oxide, boron nitride, gallium phosphide, or titanium nitride.

10. A method comprising:
depositing a first de-bond layer over a first substrate;
depositing a first silicon layer over the first de-bond layer;
depositing a second de-bond layer over the first silicon layer;
depositing a second silicon layer over the second de-bond layer;
epitaxially growing a first semiconductor layer and a second semiconductor layer over the second silicon layer;
epitaxially growing a third semiconductor layer and a fourth semiconductor layer over a second substrate;
depositing a first bonding layer over the second semiconductor layer;
depositing a second bonding layer over the fourth semiconductor layer;
bonding the first bonding layer to the second bonding layer to form a bonded layer; and
after bonding the first bonding layer to the second bonding layer, ablating the first de-bond layer, the first silicon layer, and the second de-bond layer using a laser anneal process to de-bond the first substrate from the second silicon layer, the first semiconductor layer, and the second semiconductor layer.

11. The method of claim 10 further comprising:
patterning the third semiconductor layer, the fourth semiconductor layer, the bonded layer, the second semiconductor layer, and the first semiconductor layer to define a fin extending upwards from the first substrate.

12. The method of claim 11 further comprising:
patterning source/drain recesses in the fin;
forming first source/drains in the source/drain recesses;
depositing a first isolation layer over the first source/drains; and
forming second source/drains in the source/drain recesses over the first isolation layer.

13. The method of claim 10, wherein a thickness of each of the first de-bond layer and the second de-bond layer is in a range from 1 nm to 10 nm.

14. The method of claim 10, wherein the laser anneal process comprises using a laser beam that is emitted from a laser to heat the first de-bond layer, the first silicon layer, and the second de-bond layer.

15. The method of claim 14, wherein the laser operates in an infrared region with a wavelength that is in a range from 500 to 2500 nm.

16. A method comprising:
forming a first de-bond structure over a first substrate, wherein the first de-bond structure comprises a resonant cavity, and wherein the first de-bond structure comprises:
a first de-bond layer;
a first semiconductor layer over the first de-bond layer; and
a second de-bond layer over the first semiconductor layer;
epitaxially growing a first multi-layer stack over the first de-bond structure;
bonding the first multi-layer stack to a second multi-layer stack; and
performing a first laser annealing process using a laser beam having a wavelength that matches a resonant frequency of the resonant cavity in order to ablate the first semiconductor layer and portions of the first de-bond layer and the second de-bond layer, and wherein performing the first laser annealing process results in a de-bonding of the first substrate from the first multi-layer stack.

17. The method of claim 16 further comprising:
patterning the first multi-layer stack and the second multi-layer stack to form a fin, the fin comprising a plurality of lower nanostructures alternatingly stacked with first dummy nanostructures and a plurality of upper nanostructures over the plurality of lower nanostructures, the plurality of upper nanostructures being alternatingly stacked with second dummy nanostructures;
replacing the first dummy nanostructures with a first gate stack, the first gate stack surrounding each of the plurality of lower nanostructures; and
replacing the second dummy nanostructures with a second gate stack, the second gate stack surrounding each of the plurality of upper nanostructures.

18. The method of claim 16, wherein the first semiconductor layer comprises silicon, and wherein a thickness of the first semiconductor layer is in a range from 5 nm to 200 nm.

19. The method of claim 16, wherein the first de-bond layer and the second de-bond layer comprise yttrium oxide, cerium oxide, boron nitride or gallium phosphide.

20. The method of claim 16, wherein a thickness of each of the first de-bond layer and the second de-bond layer is in a range from 1 nm to 10 nm.
